(19) United States
(12) Patent Application Publication
(10) Pub. No.: US 2024/0319269 A1
(43) Pub. Date: Sep. 26, 2024

(54) MEMORY TIMING CHARACTERIZATION CIRCUITRY

(71) Applicant: Intel Corporation, Santa Clara, CA (US)

(72) Inventors: Amit Agarwal, Hillsboro, OR (US); Steven K. Hsu, Lake Oswego, OR (US); Mark A. Anders, Hillsboro, OR (US); Ram Kumar Krishnamurthy, Portland, OR (US)

(21) Appl. No.: 18/124,338

(22) Filed: Mar. 21, 2023

(51) Int. Cl. G01R 31/317; G01R 31/3185

(52) U.S. Cl. CPC G01R 31/31725; G01R 31/31713; G01R 31/318536

(57) ABSTRACT

An apparatus includes a plurality of delay generators, a first plurality of flip-flop circuits, a second plurality of flip-flop circuits, and a third plurality of flip-flop circuits. The plurality of delay generators includes a data delay generator, an enable delay generator, and a reference delay generator. The first plurality of flip-flop circuits is coupled to the data delay generator to receive a delayed data input signal, and provide the delayed data input signal to a plurality of data input terminals of a memory circuit. The second plurality of flip-flop circuits is coupled to the enable delay generator to receive a delayed enable signal and provide the delayed enable signal to a plurality of enable terminals of the memory circuit. The third plurality of flip-flop circuits is coupled to an output terminal of the memory circuit. The reference delay generator provides a synchronized clock signal to the flip-flop circuits.

### TECHNICAL FIELD

Embodiments pertain to improvements in memory architectures, including techniques for memory timing characterization including the configuration of on-chip high-resolution timing characterization circuitry for memory intellectual property (IP).

### BACKGROUND

As process technology advances, design technology co-optimization (DTCO) can be used to extract optimal power, performance, area (PPA), and minimum supply voltage (VMIN) by exploiting new process scaling boosters (e.g., buried power rail, gate-all-around (GAA), and complementary field-effect transistors (FETs)) for improved silicon memory and standard cell circuit IPs. One of the key DTCO methodologies is to perform silicon IP characterization for PPA and robustness as newer process technology matures. This also provides confidence for IP adoption, improved library models with silicon correlation to foundry customers, and in-field testing to detect hardware failure/chip-telemetry.

Memory IPs are key building blocks in high-performance microprocessors, discrete graphics, and hardware accelerators, where the impact of timing variations and margin on clock frequency has become increasingly critical due to emerging applications such as machine learning, computer vision, and autonomous driving.

### BRIEF DESCRIPTION OF THE DRAWINGS

In the drawings, like numerals may describe the same or similar components or features in different views. Like numerals having different letter suffixes may represent different instances of similar components. Some embodiments are illustrated by way of example, and not limitation, in the figures of the accompanying drawings in which:

FIG. 1 is a block diagram of a radio architecture including an interface card with a memory device configured according to disclosed techniques, in accordance with some embodiments;

FIG. 2 illustrates a front-end module circuitry for use in the radio architecture of FIG. 1, in accordance with some embodiments;

FIG. 3 illustrates a radio IC circuitry for use in the radio architecture of FIG. 1, in accordance with some embodiments;

FIG. 4 illustrates a baseband processing circuitry for use in the radio architecture of FIG. 1, in accordance with some embodiments;

FIG. 5 illustrates an example computing system with a memory device configured according to disclosed techniques, in accordance with some embodiments;

FIG. 6 illustrates a block diagram of an example processor and/or SoC that may have one or more cores, an integrated memory controller, and a memory device configured according to disclosed techniques, in accordance with some embodiments;

FIG. 7 is a block diagram illustrating both an example in-order pipeline and an example register renaming, out-of-order issue/execution pipeline in accordance with some embodiments;

FIG. 8 is a block diagram illustrating both an example in-order architecture core and an example register renaming, out-of-order issue/execution architecture core to be included in a processor in accordance with some embodiments;

FIG. 9 is a block diagram of sequential timing test bench circuitry, in accordance with some embodiments;

FIG. 10 is a block diagram of memory IP timing test bench circuitry, in accordance with some embodiments;

FIG. 11 is a block diagram of memory IP timing characterization circuitry with multiple delay generators, in accordance with some embodiments;

FIG. 12 is a block diagram of a delay generator circuit, in accordance with some embodiments;

FIG. 13 is a diagram of delay chain measurements for the delay generator circuit of FIG. 12, in accordance with some embodiments;

FIG. 14 is a diagram of a reference scan chain for 12 testing and 6 memory execution clock cycles for the delay generator circuit of FIG. 12, in accordance with some embodiments;

FIG. 15 is a diagram of reference scan chains for a 3-edge clock/enable generation circuit with a programmable delay pulse, in accordance with some embodiments;

FIG. 16 is a block diagram of a regional capture flip-flop (RCFF) with a rising select XOR gate, in accordance with some embodiments;

FIG. 17 is a diagram of relative placement and pre-routing of delay cells and RCFFs to minimize measurement errors due to layout/routing mismatch, in accordance with some embodiments;

FIG. 18 illustrates a table with a bisectional algorithm example, in accordance with some embodiments;

FIG. 19 illustrates clk2q and read address setup time characterization methodology, in accordance with some embodiments;

FIG. 20 illustrates states for clk2q and read address setup for the time characterization methodology of FIG. 19, in accordance with some embodiments;

FIG. 21 illustrates write address setup and write-cycle-time characterization methodology, in accordance with some embodiments;

FIG. 22 illustrates states for write address setup and write cycle time for the time characterization methodology of FIG. 21, in accordance with some embodiments;

FIG. 23 is a flow diagram of an example method for memory timing characterization, in accordance with some embodiments; and

FIG. 24 illustrates a block diagram of an example machine upon which any one or more of the operations/techniques (e.g., methodologies) discussed herein may perform.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc., to provide a thorough understanding of the various aspects of various embodiments. However, it will be apparent to those skilled in the art having the benefit of the present disclosure that the various aspects of the various embodiments may be practiced in other examples that depart from these specific details. In certain instances, descriptions of well-known devices, circuits, and methods are omitted so as not to obscure the description of the various embodiments with unnecessary detail.

The following description and the drawings sufficiently illustrate specific embodiments to enable those skilled in the art to practice them. Other embodiments may incorporate structural, logical, electrical, process, and other changes. Portions and features of some embodiments may be included in or substituted for, those of other embodiments. Embodiments outlined in the claims encompass all available equivalents of those claims.

The term “PMOS transistor” refers to a P-type metal oxide semiconductor field effect transistor. Likewise, “NMOS transistor” refers to an N-type metal oxide semiconductor field effect transistor. It should be appreciated that whenever the terms: “transistor”, “MOS transistor”, “NMOS transistor”, or “PMOS transistor” are used, unless otherwise expressly indicated or dictated by the nature of their use, they are being used in an exemplary manner. They encompass the different varieties of MOS devices including devices with different VTs, materials, insulator thicknesses, and gate(s) configurations, to mention just a few. Moreover, unless specifically referred to as MOS, TFET, CFET, or other, the term transistor can encompass other suitable transistor types, e.g., junction-field-effect transistors, bipolar-junction transistors, metal-semiconductor FETs, and various types of three-dimensional transistors, known today or not yet developed.

The term “channel” refers to a transmission path through which a signal (X(t) in the depicted figure) propagates from a transmitter output to a receiver input. It may include combinations of conductive traces, wireless paths, and/or optical transmission media. For example, it could include combinations of packaging components (e.g., bond wires, solder balls), package traces, sockets, printed-circuit board (PCB) traces, cables (e.g., coaxial, ribbon, twisted pair), wave guides, air (and any other wireless transmission media), optical cable (and other optical transmission components), and so on. It may also include higher-level components for driving, routing, and/or switching signals onto or off of the channel.

As used herein, the term “chip” (or die) refers to a piece of a material, such as a semiconductor material, that includes a circuit such as an integrated circuit or a part of an integrated circuit.

The term memory IP indicates memory intellectual property. The terms memory IP, memory device, memory chip, and memory are interchangeable.

A chipset is an integrated circuit block that has been designed to work with other chipsets to form larger more complex processing modules. In such modules, a system is subdivided into circuit blocks, called “chipsets”, that are often made of reusable IP blocks. They typically are formed on a single semiconductor die but may comprise multiple dies or die components. A benefit of employing chipsets to make a processing module is that they may be formed from different process nodes with different associated strengths, costs, etc. In addition, in many cases, it is easier to make smaller chipsets forming a larger, overall processing system rather than implementing the system on a single die.

The disclosed techniques include configuring a hardware test bench (also referred to as memory timing characterization circuitry) to measure on-chip timing parameters with high resolution for memory IPs (such as setup, hold, clock-to-q time, and cycle time). Such memory timing test-bench can be part of memory built-in self-test (BIST) and can be used to enhance the BIST testing coverage. In some aspects, the disclosed techniques include measuring on-chip timing parameters for sequential elements. However, unlike sequential elements, memory IPs have additional challenges for on-chip timing measurements. These challenges include (a) multiple address, write-data, clock, and data-out inputs/outputs; (b) the physical location of inputs/outputs is not in close-proximity which adds to measurement error; and (c) complexity due to multiple input switching permutations. The disclosed techniques include a fully configurable synthesizable memory IP timing characterization test bench, featuring distributed regional capture flip-flop circuits (RCFFs) with mesh-based low skew clock, a main capture flip-flop circuit (MCFF) to measure setup difference across RCFFs, multiple data/input delay generators with high-resolution to handle timing permutations, automated relative placement/pre-routing for matched layout and XORed clock delay generators to create multiple edges for measuring read after write delay/cycle time.

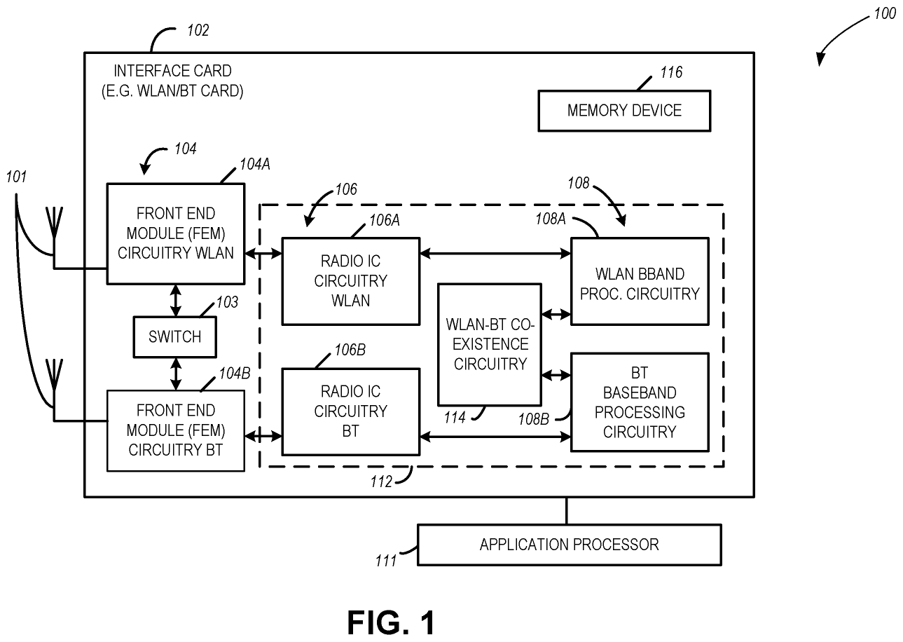

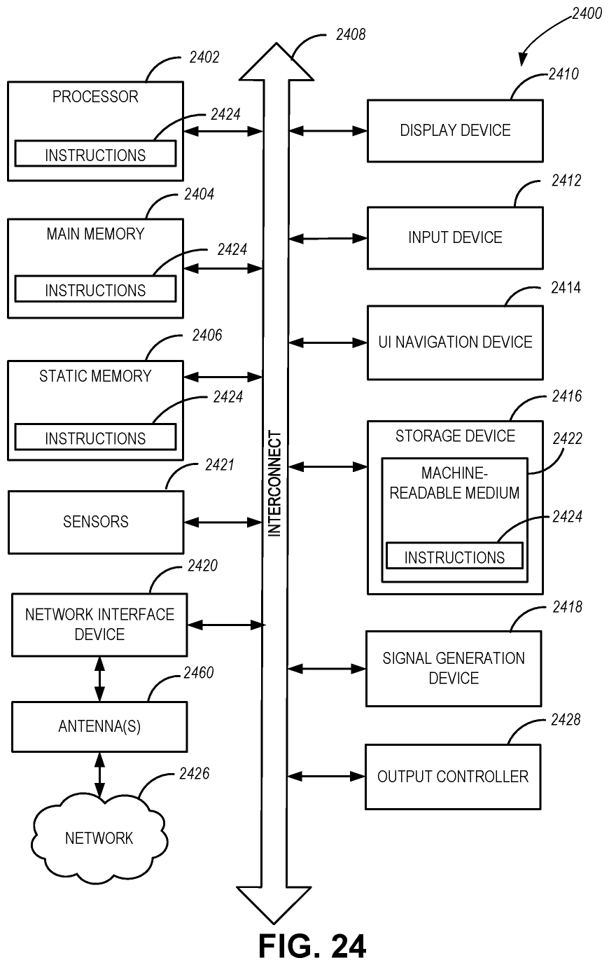

FIG. 1 is a block diagram of a radio architecture 100 including an interface card 102 with a memory device 116, in accordance with some embodiments. The radio architecture 100 may be implemented in a computing device (e.g., device 2400 in FIG. 24) including user equipment (UE), a base station (e.g., a next-generation Node-B (gNB), enhanced Node-B (eNB)), a smartphone, a personal computer (PC), a laptop, a tablet, or another type of wired or wireless device. The radio architecture 100 may include radio front-end module (FEM) circuitry 104, radio integrated circuit (IC) circuitry 106, memory device 116, and baseband processing circuitry 108 configured as part of the interface card 102. In this regard, radio architecture 100 (as shown in FIG. 1) includes an interface card 102 configured to perform both Wireless Local Area Network (WLAN) functionalities and Bluetooth (BT) functionalities (e.g., as WLAN/BT interface or modem card), although embodiments are not so limited and the disclosed techniques apply to other types of radio architectures with different types of interface cards as well. In this disclosure, “WLAN” and “Wi-Fi” are used interchangeably. Other example types of interface cards which can be used in connection with the disclosed techniques include graphics cards, network cards, SSD cards (such as M.2-based cards), CEM-based cards, etc.

FEM circuitry 104 may include a WLAN or Wi-Fi FEM circuitry 104A and a Bluetooth (BT) FEM circuitry 104B. The WLAN FEM circuitry 104A may include a receive signal path comprising circuitry configured to operate on WLAN RF signals received from one or more antennas 101, to amplify the received signals, and provide the amplified versions of the received signals to the WLAN radio IC circuitry 106A for further processing. The BT FEM circuitry 104B may include a receive signal path which may include circuitry configured to operate on BT RF signals received from the one or more antennas 101, to amplify the received signals, and provide the amplified versions of the received signals to the BT radio IC circuitry 106B for further processing. The WLAN FEM circuitry 104A may also include a transmit signal path which may include circuitry configured to amplify WLAN signals provided by the radio IC circuitry 106A for wireless transmission by the one or more antennas 101. Besides, the BT FEM circuitry 104B may also include a transmit signal path which may include circuitry configured to amplify BT signals provided by the radio IC circuitry 106B for wireless transmission by the one or more antennas. In the embodiment of FIG. 1, although WLAN FEM circuitry 104A and BT FEM circuitry 104B are shown as being distinct from one another, embodiments are not so limited and include within their scope the use of a FEM (not shown) that includes a transmit path and/or a receive path for both WLAN and BT signals, or the use of one or more FEM circuitries where at least some of the FEM circuitries share transmit and/or receive signal paths for both WLAN and BT signals.

Radio IC circuitry 106 as shown may include WLAN radio IC circuitry 106A and BT radio IC circuitry 106B. The WLAN radio IC circuitry 106A may include a receive signal path which may include circuitry to down-convert WLAN RF signals received from the WLAN FEM circuitry 104A and provide baseband signals to WLAN baseband processing circuitry 108A. The BT radio IC circuitry 106B may, in turn, include a receive signal path which may include circuitry to down-convert BT RF signals received from the BT FEM circuitry 104B and provide baseband signals to BT baseband processing circuitry 108B. The WLAN radio IC circuitry 106A may also include a transmit signal path which may include circuitry to up-convert WLAN baseband signals provided by the WLAN baseband processing circuitry 108A and provide WLAN RF output signals to the WLAN FEM circuitry 104A for subsequent wireless transmission by the one or more antennas 101. The BT radio IC circuitry 106B may also include a transmit signal path which may include circuitry to up-convert BT baseband signals provided by the BT baseband processing circuitry 108B and provide BT RF output signals to the BT FEM circuitry 104B for subsequent wireless transmission by the one or more antennas 101. In the embodiment of FIG. 1, although radio IC circuitries 106A and 106B are shown as being distinct from one another, embodiments are not so limited and include within their scope the use of a radio IC circuitry (not shown) that includes a transmit signal path and/or a receive signal path for both WLAN and BT signals, or the use of one or more radio IC circuitries where at least some of the radio IC circuitries share transmit and/or receive signal paths for both WLAN and BT signals.

Baseband processing circuitry 108 may include a WLAN baseband processing circuitry 108A and a BT baseband processing circuitry 108B. The WLAN baseband processing circuitry 108A may include a memory, such as, for example, a set of RAM arrays in a Fast Fourier Transform (FFT) or Inverse Fast Fourier Transform (IFFT) block (not shown) of the WLAN baseband processing circuitry 108A. Each of the WLAN baseband processing circuitry 108A and the BT baseband processing circuitry 108B may further include one or more processors and control logic to process the signals received from the corresponding WLAN or BT receive signal path of the radio IC circuitry 106, and to also generate corresponding WLAN or BT baseband signals for the transmit signal path of the radio IC circuitry 106. Each of the baseband processing circuitries 108A and 108B may further include a physical layer (PHY) and medium access control layer (MAC) circuitry and may further interface with a host processor (e.g., the application processor 111) in a host system (e.g., a host SoC) for generation and processing of the baseband signals and for controlling operations of the radio IC circuitry 106 (including controlling the operation of the memory device 116).

Referring still to FIG. 1, according to the shown embodiment, WLAN-BT coexistence circuitry 114 may include logic providing an interface between the WLAN baseband processing circuitry 108A and the BT baseband processing circuitry 108B to enable use cases requiring WLAN and BT coexistence. In addition, a switch 103 may be provided between the WLAN FEM circuitry 104A and the BT FEM circuitry 104B to allow switching between the WLAN and BT radios according to application needs. In addition, although the one or more antennas 101 are depicted as being respectively connected to the WLAN FEM circuitry 104A and the BT FEM circuitry 104B, embodiments include within their scope the sharing of the one or more antennas 101 as between the WLAN and BT FEMs, or the provision of more than one antenna connected to each of FEM circuitries 104A or 104B.

In some embodiments, the front-end module circuitry 104, the radio IC circuitry 106, and the baseband processing circuitry 108 may be provided on a single radio card, such as the interface card 102. In some other embodiments, the one or more antennas 101, the FEM circuitry 104, and the radio IC circuitry 106 may be provided on a single radio card. In some other embodiments, the radio IC circuitry 106 and the baseband processing circuitry 108 may be provided on a single chip or IC, such as IC 112.

In some embodiments, the interface card 102 can be configured as a wireless radio card, such as a WLAN radio card configured for wireless communications (e.g., WiGig communications in the 60 GHz range or mmW communications in the 24.24 GHz-52.6 GHz range), although the scope of the embodiments is not limited in this respect. In some of these embodiments, the radio architecture 100 may be configured to receive and transmit orthogonal frequency division multiplexed (OFDM) or orthogonal frequency division multiple access (OFDMA) communication signals over a multicarrier communication channel. The OFDM or OFDMA signals may comprise a plurality of orthogonal subcarriers.

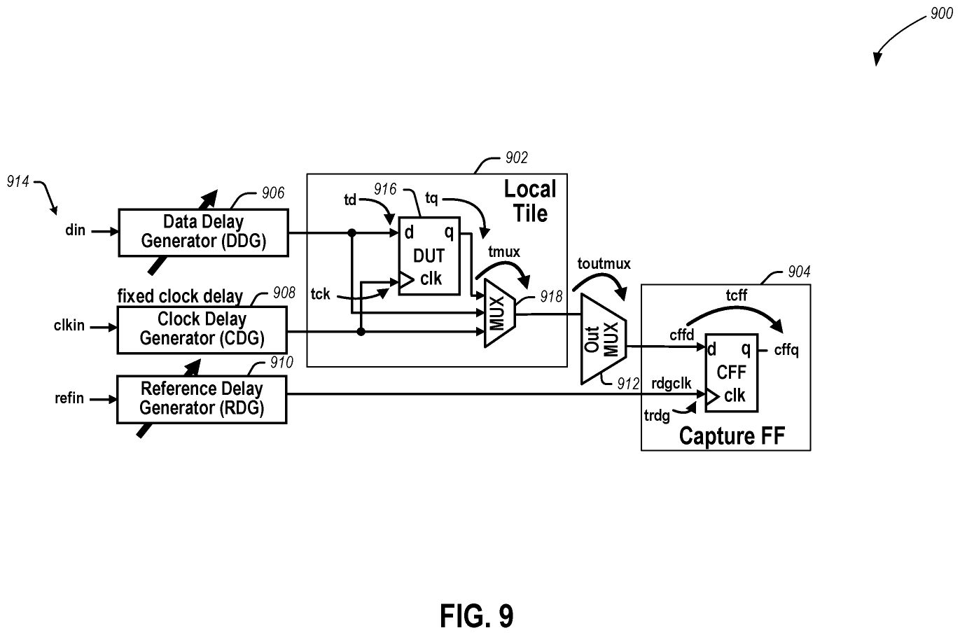

In some embodiments, the interface card 102 may include one or more memory devices such as memory device 116. Memory device 116 can be configured based on the disclosed techniques. In this regard, memory device 116 can be the same as, or include, one or more of the memory devices discussed in connection with FIGS. 9-24. Configuring (including testing) the memory device 116 (or any of the memory devices discussed herein) can be based on one or more of the techniques discussed in connection with FIGS. 9-24.

In some of these multicarrier embodiments, radio architecture 100 may be a part of a Wi-Fi communication station (STA) such as a wireless access point (AP), a base station, or a mobile device including a Wi-Fi-enabled device. In some of these embodiments, radio architecture 100 may be configured to transmit and receive signals in accordance with specific communication standards and/or protocols, such as any of the Institute of Electrical and Electronics Engineers (IEEE) standards including, 802.11n-2009, IEEE 802.11-2012, 802.11n-2009, 802.11ac, IEEE 802.11-2016, 802.11ad, and/or 802.11ax standards and/or proposed specifications for WLANs, although the scope of embodiments is not limited in this respect and operations using other wireless standards can also be configured. Radio architecture 100 may also be suitable to transmit and/or receive communications in accordance with other techniques and standards, including a 3rd Generation Partnership Project (3GPP) standard, including a communication standard used in connection with 5G or new radio (NR) communications.

In some embodiments, the radio architecture 100 may be configured for high-efficiency (HE) Wi-Fi communications in accordance with the IEEE 802.11ax standard or another standard associated with wireless communications. In these embodiments, the radio architecture 100 may be configured to communicate in accordance with an OFDMA technique, although the scope of the embodiments is not limited in this respect.

In some other embodiments, the radio architecture 100 may be configured to transmit and receive signals transmitted using one or more other modulation techniques such as spread spectrum modulation (e.g., direct sequence code division multiple access (DS-CDMA) and/or frequency hopping code division multiple access (FH-CDMA)), time-division multiplexing (TDM) modulation, and/or frequency-division multiplexing (FDM) modulation, although the scope of the embodiments is not limited in this respect.

In some embodiments, as further shown in FIG. 1, the BT baseband processing circuitry 108B may be compliant with a Bluetooth (BT) connectivity standard such as Bluetooth, Bluetooth 4.0 or Bluetooth 5.0, or any other iteration of the Bluetooth Standard. In embodiments that include BT functionality as shown for example in FIG. 1, the radio architecture 100 may be configured to establish a BT synchronous connection-oriented (SCO) link and or a BT low energy (BT LE) link. In some of the embodiments that include functionality, the radio architecture 100 may be configured to establish an extended SCO (eSCO) link for BT communications, although the scope of the embodiments is not limited in this respect. In some of these embodiments that include a BT functionality, the radio architecture may be configured to engage in a BT Asynchronous Connection-Less (ACL) communications, although the scope of the embodiments is not limited in this respect. In some embodiments, as shown in FIG. 1, the functions of a BT radio card and WLAN radio card may be combined on a single wireless radio card, such as the interface card 102, although embodiments are not so limited, and include within their scope discrete WLAN and BT radio cards

In some embodiments, the radio architecture 100 may include other radio cards, such as a cellular radio card configured for cellular/wireless communications (e.g., 3GPP such as LTE, LTE-Advanced, WiGig, or 5G communications including mmW communications), which may be implemented together with (or as part of) the interface card 102.

In some IEEE 802.11 embodiments, the radio architecture 100 may be configured for communication over various channel bandwidths including bandwidths having center frequencies of about 900 MHZ, 2.4 GHz, 5 GHZ, and bandwidths of about 1 MHZ, 2 MHZ, 2.5 MHz, 4 MHZ, 5 MHz, 8 MHz, 10 MHz, 16 MHz, 20 MHz, 40 MHz, 80 MHz (with contiguous bandwidths) or 80+80 MHz (160 MHz) (with non-contiguous bandwidths). In some embodiments, a 320 MHz channel bandwidth may be used. The scope of the embodiments is not limited with respect to the above center frequencies, however.

In some embodiments, memory device 116 is configured as cache memory, including array and queues used in high-performance microprocessor CPU/GPU designs. Other use cases of the disclosed memory devices can be configured as well.

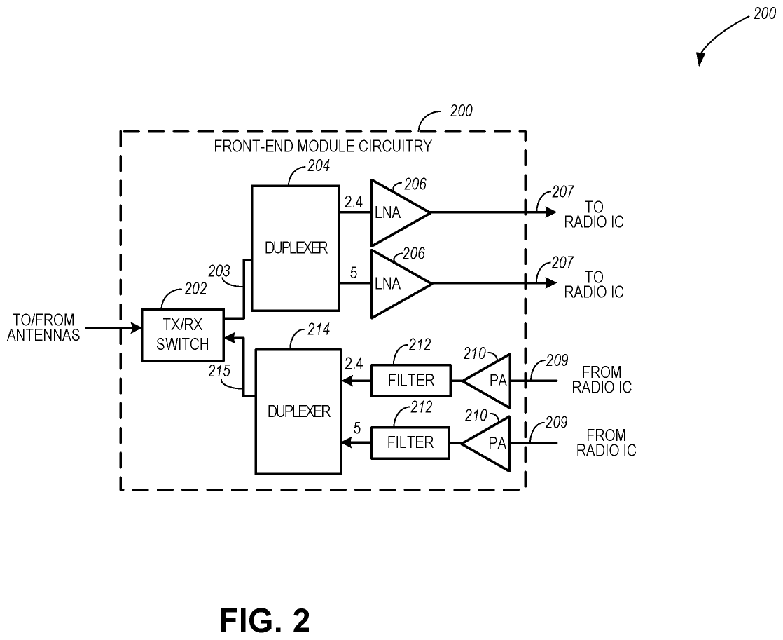

FIG. 2 illustrates FEM circuitry 200 in accordance with some embodiments. The FEM circuitry 200 is one example of circuitry that may be suitable for use as the WLAN and/or BT FEM circuitry 104A/104B (FIG. 1), although other circuitry configurations may also be suitable.

In some embodiments, the FEM circuitry 200 may include a TX/RX switch 202 to switch between transmit (TX) mode and receive (RX) mode operation. In some aspects, a diplexer may be used in place of a TX/RX switch. The FEM circuitry 200 may include a receive signal path and a transmit signal path. The receive signal path of the FEM circuitry 200 may include a low-noise amplifier (LNA) 206 to amplify received RF signals 203 and provide the amplified received RF signals 207 as an output (e.g., to the radio IC circuitry 106 (FIG. 1)). The transmit signal path of the FEM circuitry 200 may include a power amplifier (PA) to amplify input RF signals 209 (e.g., provided by the radio IC circuitry 106), and one or more filters 212, such as band-pass filters (BPFs), low-pass filters (LPFs) or other types of filters, to generate RF signals 215 for subsequent transmission (e.g., by the one or more antennas 101 (FIG. 1)).

In some dual-mode embodiments for Wi-Fi communication, the FEM circuitry 200 may be configured to operate in, e.g., either the 2.4 GHz frequency spectrum or the 5 GHz frequency spectrum. In these embodiments, the receive signal path of the FEM circuitry 200 may include a receive signal path duplexer 204 to separate the signals from each spectrum as well as provide a separate LNA 206 for each spectrum as shown. In these embodiments, the transmit signal path of the FEM circuitry 200 may also include a power amplifier (PA) 210 and one or more filters 212, such as a BPF, an LPF, or another type of filter for each frequency spectrum, and a transmit signal path duplexer 214 to provide the signals of one of the different spectrums onto a single transmit path for subsequent transmission by the one or more antennas 101 (FIG. 1). In some embodiments, BT communications may utilize the 2.4 GHz signal path and may utilize the same FEM circuitry 200 as the one used for WLAN communications.

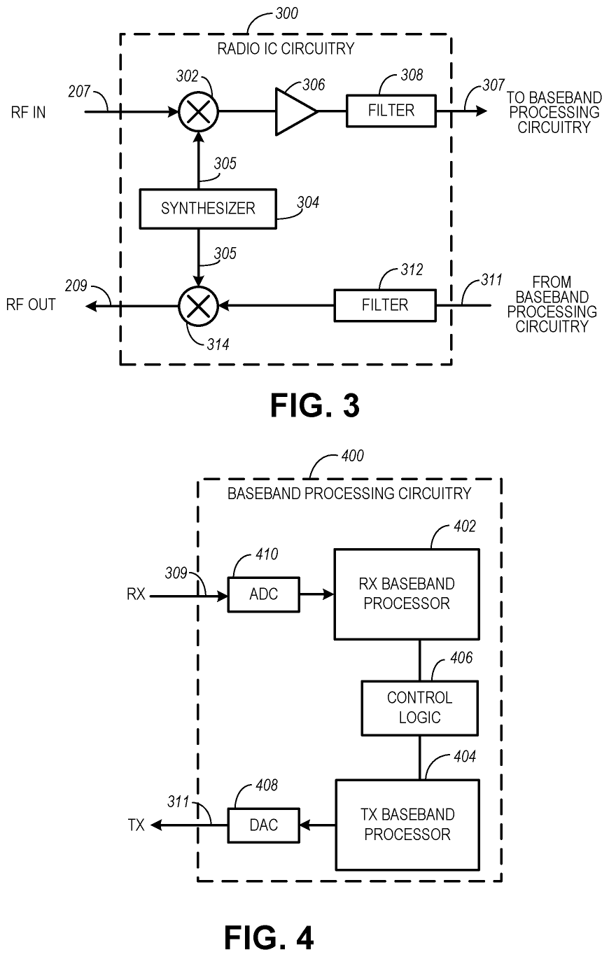

FIG. 3 illustrates radio IC circuitry 300 in accordance with some embodiments. The radio IC circuitry 300 is one example of circuitry that may be suitable for use as the WLAN or BT radio IC circuitry 106A/106B (FIG. 1), although other circuitry configurations may also be suitable.

In some embodiments, the radio IC circuitry 300 may include a receive signal path and a transmit signal path. The receive signal path of the radio IC circuitry 300 may include mixer circuitry 302, such as, for example, down-conversion mixer circuitry, amplifier circuitry 306, and filter circuitry 308. The transmit signal path of the radio IC circuitry 300 may include at least filter circuitry 312 and mixer circuitry 314, such as up-conversion mixer circuitry. Radio IC circuitry 300 may also include synthesizer circuitry 304 for synthesizing a frequency 305 for use by the mixer circuitry 302 and the mixer circuitry 314. The mixer circuitry 302 and/or 314 may each, according to some embodiments, be configured to provide direct conversion functionality. The latter type of circuitry presents a much simpler architecture as compared with standard super-heterodyne mixer circuitries, and any flicker noise brought about by the same may be alleviated for example through the use of OFDM modulation. FIG. 3 illustrates only a simplified version of a radio IC circuitry and may include, although not shown, embodiments where each of the depicted circuitries may include more than one component. For instance, mixer circuitry 302 and/or 314 may each include one or more mixers, and filter circuitries 308 and/or 312 may each include one or more filters, such as one or more BPFs and/or LPFs according to application needs. For example, when mixer circuitries are of the direct-conversion type, they may each include two or more mixers.

In some embodiments, mixer circuitry 302 may be configured to down-convert RF signals 207 received from the FEM circuitry 104 (FIG. 1) based on the synthesized frequency 305 provided by the synthesizer circuitry 304. The amplifier circuitry 306 may be configured to amplify the down-converted signals and the filter circuitry 308 may include an LPF configured to remove unwanted signals from the down-converted signals to generate output baseband signals 307. Output baseband signals 307 may be provided to the baseband processing circuitry 108 (FIG. 1) for further processing. In some embodiments, the output baseband signals 307 may be zero-frequency baseband signals, although this is not a requirement. In some embodiments, mixer circuitry 302 may comprise passive mixers, although the scope of the embodiments is not limited in this respect.

In some embodiments, the mixer circuitry 314 may be configured to up-convert input baseband signals 311 based on the synthesized frequency 305 provided by the synthesizer circuitry 304 to generate RF output signals 209 for the FEM circuitry 104. The baseband signals 311 may be provided by the baseband processing circuitry 108 and may be filtered by filter circuitry 312. The filter circuitry 312 may include an LPF or a BPF, although the scope of the embodiments is not limited in this respect.

In some embodiments, the mixer circuitry 302 and the mixer circuitry 314 may each include two or more mixers and may be arranged for quadrature down-conversion and/or up-conversion respectively with the help of the synthesizer circuitry 304. In some embodiments, the mixer circuitry 302 and the mixer circuitry 314 may each include two or more mixers each configured for image rejection (e.g., Hartley image rejection). In some embodiments, the mixer circuitry 302 and the mixer circuitry 314 may be arranged for direct down-conversion and/or direct up-conversion, respectively. In some embodiments, the mixer circuitry 302 and the mixer circuitry 314 may be configured for super-heterodyne operation, although this is not a requirement.

Mixer circuitry 302 may comprise, according to one embodiment: quadrature passive mixers (e.g., for the in-phase (I) and quadrature-phase (Q) paths). In such an embodiment, RF input signal 207 from FIG. 2 may be down-converted to provide I and Q baseband output signals to be sent to the baseband processor.

Quadrature passive mixers may be driven by zero and ninety-degree time-varying LO switching signals provided by a quadrature circuitry which may be configured to receive a LO frequency (fLO) from a local oscillator or a synthesizer, such as LO frequency 305 of synthesizer circuitry 304 (FIG. 3). In some embodiments, the LO frequency may be the carrier frequency, while in other embodiments, the LO frequency may be a fraction of the carrier frequency (e.g., one-half the carrier frequency, one-third the carrier frequency). In some embodiments, the zero and ninety-degree time-varying switching signals may be generated by the synthesizer, although the scope of the embodiments is not limited in this respect.

In some embodiments, the LO signals may differ in the duty cycle (the percentage of one period in which the LO signal is high) and/or offset (the difference between the start points of the period). In some embodiments, the LO signals may have a 25% duty cycle and a 50% offset. In some embodiments, each branch of the mixer circuitry (e.g., the in-phase (I) and quadrature-phase (Q) path) may operate at a 25% duty cycle, which may result in a significant reduction in power consumption.

The RF input signal 207 (FIG. 2) may comprise a balanced signal, although the scope of the embodiments is not limited in this respect. The I and Q baseband output signals may be provided to the low-noise amplifier, such as amplifier circuitry 306 (FIG. 3) or filter circuitry 308 (FIG. 3).

In some embodiments, the output baseband signals 307 and the input baseband signals 311 may be analog, although the scope of the embodiments is not limited in this respect. In some alternate embodiments, the output baseband signals 307 and the input baseband signals 311 may be digital. In these alternate embodiments, the radio IC circuitry may include an analog-to-digital converter (ADC) and digital-to-analog converter (DAC) circuitry.

In some dual-mode embodiments, a separate radio IC circuitry may be provided for processing signals for each spectrum, or for other spectrums not mentioned here, although the scope of the embodiments is not limited in this respect.

In some embodiments, the synthesizer circuitry 304 may be a fractional-N synthesizer or a fractional N/N+1 synthesizer, although the scope of the embodiments is not limited in this respect as other types of frequency synthesizers may be suitable. In some embodiments, the synthesizer circuitry 304 may be a delta-sigma synthesizer, a frequency multiplier, or a synthesizer comprising a phase-locked loop with a frequency divider. According to some embodiments, the synthesizer circuitry 304 may include a digital frequency synthesizer circuitry. An advantage of using a digital synthesizer circuitry is that, although it may still include some analog components, its footprint may be scaled down much more than the footprint of an analog synthesizer circuitry. In some embodiments, frequency input into synthesizer circuitry 304 may be provided by a voltage-controlled oscillator (VCO), although that is not a requirement. A divider control input may further be provided by either the baseband processing circuitry 108 (FIG. 1) or the host processor 111 (FIG. 1) depending on the desired output frequency 305. In some embodiments, a divider control input (e.g., N) may be determined from a look-up table (e.g., within a Wi-Fi card) based on a channel number and a channel center frequency as determined or indicated by the host processor 111.

In some embodiments, synthesizer circuitry 304 may be configured to generate a carrier frequency as the output frequency 305, while in other embodiments, the output frequency 305 may be a fraction of the carrier frequency (e.g., one-half of the carrier frequency, one-third of the carrier frequency). In some embodiments, the output frequency 305 may be an LO frequency (fLO).

FIG. 4 illustrates a baseband processing circuitry 400 for use in the radio architecture of FIG. 1, in accordance with some embodiments. The baseband processing circuitry 400 is one example of circuitry that may be suitable for use as the baseband processing circuitry 108 (FIG. 1), although other circuitry configurations may also be suitable. The baseband processing circuitry 400 may include a receive baseband processor (RX BBP) 402 for processing receive baseband signals 309 provided by the radio IC circuitry 106 (FIG. 1) and a transmit baseband processor (TX BBP) 404 for generating transmit baseband signals 311 for the radio IC circuitry 106. The baseband processing circuitry 400 may also include control logic 406 for coordinating the operations of the baseband processing circuitry 400.

In some embodiments (e.g., when analog baseband signals are exchanged between the baseband processing circuitry 400 and the radio IC circuitry 106), the baseband processing circuitry 400 may include an analog-to-digital converter (ADC) 410 to convert analog baseband signals 309 received from the radio IC circuitry 106 to digital baseband signals for processing by the RX BBP 402. In these embodiments, the baseband processing circuitry 400 may also include a digital-to-analog converter (DAC) 408 to convert digital baseband signals from the TX BBP 404 to analog baseband signals 311.

In some embodiments that communicate OFDM signals or OFDMA signals, such as through the WLAN baseband processing circuitry 108A, the TX BBP 404 may be configured to generate OFDM or OFDMA signals as appropriate for transmission by performing an inverse fast Fourier transform (IFFT). The RX BBP 402 may be configured to process received OFDM signals or OFDMA signals by performing an FFT. In some embodiments, the RX BBP 402 may be configured to detect the presence of an OFDM signal or OFDMA signal by performing an autocorrelation, to detect a preamble, such as a short preamble, and performing a cross-correlation, to detect a long preamble. The preambles may be part of a predetermined frame structure for Wi-Fi communication.

Referring back to FIG. 1, in some embodiments, the one or more antennas 101 (FIG. 1) may each comprise one or more directional or omnidirectional antennas, including, for example, dipole antennas, monopole antennas, patch antennas, loop antennas, microstrip antennas or other types of antennas suitable for transmission of RF signals. In some multiple-input multiple-output (MIMO) embodiments, the antennas may be effectively separated to take advantage of spatial diversity and the different channel characteristics that may result. The one or more antennas 101 may each include a set of phased-array antennas, although embodiments are not so limited.

Although the radio architecture 100 is illustrated as having several separate functional elements, one or more of the functional elements may be combined and may be implemented by combinations of software-configured elements, such as processing elements including digital signal processors (DSPs), and/or other hardware elements. For example, some elements may comprise one or more microprocessors, DSPs, field-programmable gate arrays (FPGAs), application-specific integrated circuits (ASICs), radio-frequency integrated circuits (RFICs), and combinations of various hardware and logic circuitry for performing at least the functions described herein. In some embodiments, the functional elements may refer to one or more processes operating on one or more processing elements.

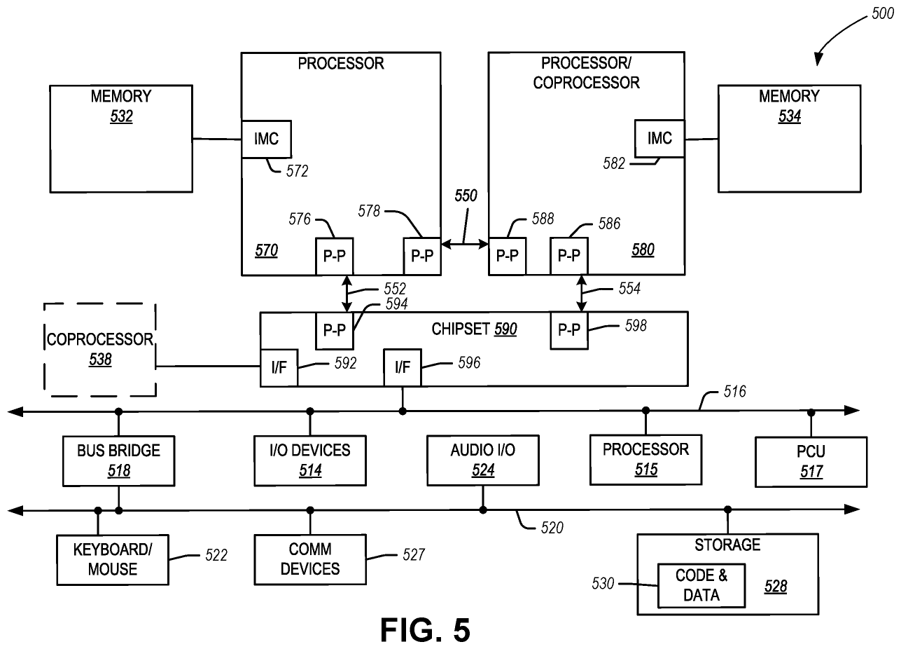

In some aspects (e.g., as discussed in connection with FIGS. 5-8), the disclosed techniques include configuring multi-port, process technology scaling-friendly, balanced P/N 8T bitcells with fully utilized diffusion areas.

FIG. 5 illustrates an example computing system with a memory device configured according to disclosed techniques, in accordance with some embodiments. Multiprocessor system 500 is interfaced and includes a plurality of processors including a first processor 570 and a second processor 580 coupled via an interface 550 such as a point-to-point (P-P) interconnect, a fabric, and/or bus. In some examples, the first processor 570, and the second processor 580 are homogeneous. In some examples, the first processor 570 and the second processor 580 are heterogenous. Though the example system 500 is shown to have two processors, the system may have three or more processors or may be a single-processor system. In some examples, the computing system is implemented, wholly or partially, with a system on a chip (SoC) or a multi-chip (or multi-chipset) module, in the same or different package combinations.

Processors 570 and 580 are shown including integrated memory controller (IMC) circuitry 572 and 582, respectively. Processor 570 also includes interface circuits 576 and 578, along with core sets. Similarly, the second processor 580 includes interface circuits 586 and 588, along with a core set as well. A core set generally refers to one or more compute cores that may or may not be grouped into different clusters, hierarchal groups, or groups of common core types. Cores may be configured differently for performing different functions and/or instructions at different performance and/or power levels. The processors may also include other blocks such as memory and other processing unit engines.

Processors 570 and 580 may exchange information via interface 550 using interface circuits 578 and 588. IMC circuitry 572 and 582 couple the processors 570 and 580 to respective memories, namely a memory 532 and a memory 534, which may be portions of main memory locally attached to the respective processors. Configuring (including testing) the memory 534 can be based on one or more of the techniques discussed in connection with FIGS. 9-24.

Processors 570 and 580 may each exchange information with a network interface (NW I/F) 590 via individual interfaces 552 and 554 using interface circuits 576, 594, 586, and 598. The network interface 590 (e.g., one or more of an interconnect, bus, and/or fabric, and in some examples is a chipset) may optionally exchange information with a coprocessor 538 via an interface circuit 592. In some examples, the coprocessor 538 is a special-purpose processor, such as, for example, a high-throughput processor, a network or communication processor, compression engine, graphics processor, general-purpose graphics processing unit (GPGPU), neural-network processing unit (NPU), embedded processor, or the like.

A shared cache (not shown) may be included in either processor 570, 580 or outside of both processors, yet connected with the processors via an interface such as P-P interconnect, such that either or both processors' local cache information may be stored in the shared cache if a processor is placed into a low power mode.

Network interface 590 may be coupled to a first interface 516 via the interface circuit 596. In some examples, the first interface 516 may be an interface such as a Peripheral Component Interconnect (PCI) interconnect, a PCI Express interconnect, or another I/O interconnect. In some examples, the first interface 516 is coupled to a power control unit (PCU) 517, which may include circuitry, software, and/or firmware to perform power management operations concerning the processors 570 and 580, and/or coprocessor 538. PCU 517 provides control information to one or more voltage regulators (not shown) to cause the voltage regulator(s) to generate the appropriate regulated voltage(s). PCU 517 also provides control information to control the operating voltage generated. In various examples, PCU 517 may include a variety of power management logic units (circuitry) to perform hardware-based power management. Such power management may be wholly processor controlled (e.g., by various processor hardware, and which may be triggered by workload and/or power, thermal or other processor constraints), and/or the power management may be performed responsive to external sources (such as a platform or power management source or system software).

PCU 517 is illustrated as being present as logic separate from processor 570 and/or processor 580. In other aspects, PCU 517 may execute on a given one or more cores (not shown) of processor 570 or 580. In some aspects, PCU 517 may be implemented as a microcontroller (dedicated or general-purpose) or other control logic configured to execute its dedicated power management code, sometimes referred to as P-code. In yet other aspects, power management operations to be performed by PCU 517 may be implemented externally to a processor, such as by way of a separate power management integrated circuit (PMIC) or another component external to the processor. In yet other embodiments, power management operations to be performed by PCU 517 may be implemented within BIOS or other system software. Along these lines, power management may be performed in concert with other power control units implemented autonomously or semi-autonomously, e.g., as controllers or executing software in cores, clusters, IP blocks, and/or in other parts of the overall system.

Various I/O devices 514 may be coupled to the first interface 516, along with a bus bridge 518 which couples the first interface 516 to a second interface 520. In some examples, one or more additional processor(s) 515, such as coprocessors, high throughput many integrated cores (MIC) processors, GPGPUs, accelerators (such as graphics accelerators or digital signal processing (DSP) units), field programmable gate arrays (FPGAs), or any other processor, are coupled to the first interface 516. In some examples, the second interface 520 may be a low pin count (LPC) interface. Various devices may be coupled to the second interface 520 including, for example, a keyboard and/or mouse 522, communication devices 527, and storage circuitry 528. Storage circuitry 528 may be one or more non-transitory machine-readable storage media as described below, such as a disk drive or other mass storage device which may include instructions/code and data 530 and may implement the storage in some examples. Further, an audio I/O 524 may be coupled to the second interface 520. Note that other architectures than the point-to-point architecture described above are possible. For example, instead of the point-to-point architecture, a system such as multiprocessor system 500 may implement a multi-drop interface or other such architecture.

Processor cores may be implemented in different ways, for different purposes, and in different processors. For instance, implementations of such cores may include: 1) a general-purpose in-order core intended for general-purpose computing; 2) a high-performance general-purpose out-of-order core intended for general-purpose computing; and 3) a special purpose core intended primarily for graphics and/or scientific (throughput) computing. Implementations of different processors may include: 1) a CPU including one or more general-purpose in-order cores intended for general-purpose computing and/or one or more general-purpose out-of-order cores intended for general-purpose computing; and 2) a coprocessor including one or more special-purpose cores intended primarily for graphics and/or scientific (throughput) computing. Such different processors lead to different computer system architectures, which may include: 1) the coprocessor on a separate chip from the CPU; 2) the coprocessor on a separate die in the same package as a CPU; 3) the coprocessor on the same die as a CPU (in which case, such a coprocessor is sometimes referred to as special purpose logic, such as integrated graphics and/or scientific (throughput) logic, or as special purpose cores); and 4) a system on a chip (SoC) that may be included on the same die as the described CPU (sometimes referred to as the application core(s) or application processor(s)), the above-described coprocessor, and additional functionality. Example core architectures are described next, followed by descriptions of example processors and computer architectures.

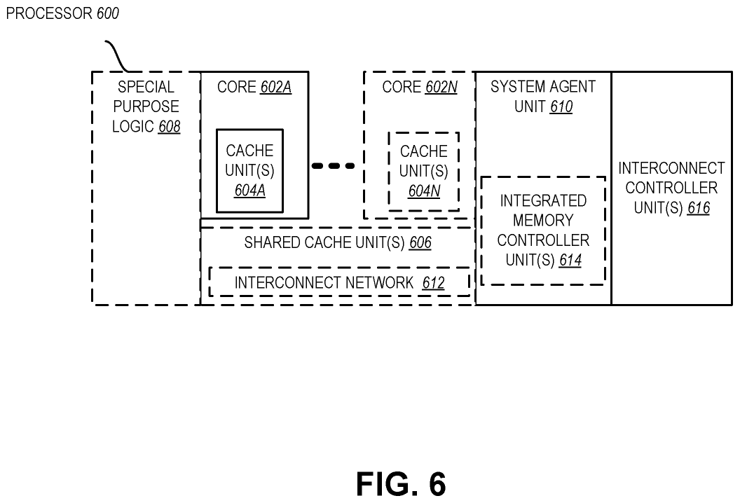

FIG. 6 illustrates a block diagram of an example processor and/or SoC 600 that may have one or more cores, an integrated memory controller, and a memory device configured according to disclosed techniques, in accordance with some embodiments. The solid lined boxes illustrate a processor 600 with a single core 602A, system agent unit circuitry 610, and a set of one or more interface controller unit(s) circuitry 616, while the optional addition of the dashed lined boxes illustrates an alternative processor 600 with multiple cores 602A-602N, a set of one or more integrated memory controller unit(s) circuitry 614 in the system agent unit circuitry 610, and special purpose logic 608, as well as a set of one or more interface controller units circuitry 616. Note that the processor 600 may be one of the processors 570 or 580, or coprocessor 538 or 515 of FIG. 5.

Thus, different implementations of the processor 600 may include: 1) a CPU with the special purpose logic 608 being integrated graphics and/or scientific (throughput) logic (which may include one or more cores, not shown), and the cores 602A-602N being one or more general purpose cores (e.g., general purpose in-order cores, general purpose out-of-order cores, or a combination of the two); 2) a coprocessor with the cores 602A-602N being a large number of special purpose cores intended primarily for graphics and/or scientific (throughput); and 3) a coprocessor with the cores 602A-602N being a large number of general purpose in-order cores. Thus, the processor 600 may be a general-purpose processor, coprocessor, or special-purpose processor, such as, for example, a network or communication processor, compression engine, graphics processor, GPGPU (general purpose graphics processing unit), a high throughput many integrated cores (MIC) coprocessor (including 30 or more cores), embedded processor, or the like. The processor may be implemented on one or more chips. The processor 600 may be a part of and/or may be implemented on one or more substrates using any of several process technologies, such as, for example, complementary metal oxide semiconductor (CMOS), bipolar CMOS (BiCMOS), P-type metal oxide semiconductor (PMOS), or N-type metal oxide semiconductor (NMOS).

A memory hierarchy includes one or more levels of cache unit(s) circuitry 604A-604N within the cores 602A-602N, a set of one or more shared cache unit(s) circuitry 606, and external memory (not shown) coupled to the set of integrated memory controller unit(s) circuitry 614. The set of one or more shared cache unit(s) circuitry 606 may include one or more mid-level caches, such as level 2 (L2), level 3 (L3), level 4 (L4), or other levels of cache, such as a last level cache (LLC), and/or combinations thereof. While in some examples interface network circuitry 612 (e.g., a ring interconnect) interfaces the special purpose logic 608 (e.g., integrated graphics logic), the set of shared cache unit(s) circuitry 606, and the system agent unit circuitry 610, alternative examples use any number of well-known techniques for interfacing such units. In some examples, coherency is maintained between one or more of the shared cache unit(s) circuitry 606 and cores 602A-602N. In some examples, interface controller units circuitry 616 couples the cores 602 to one or more other devices such as one or more I/O devices, storage, one or more communication devices (e.g., wireless networking, wired networking, etc.), etc.

In some examples, one or more of the cores 602A-602N are capable of multi-threading. The system agent unit circuitry 610 includes those components coordinating and operating cores 602A-602N. The system agent unit circuitry 610 may include, for example, power control unit (PCU) circuitry and/or display unit circuitry (not shown). The PCU may be or may include logic and components needed for regulating the power state of the cores 602A-602N and/or the special purpose logic 608 (e.g., integrated graphics logic). The display unit circuitry is for driving one or more externally connected displays.

The cores 602A-602N may be homogenous in terms of instruction set architecture (ISA). Alternatively, the cores 602A-602N may be heterogeneous in terms of ISA; that is, a subset of the cores 602A-602N may be capable of executing an ISA, while other cores may be capable of executing only a subset of that ISA or another ISA.

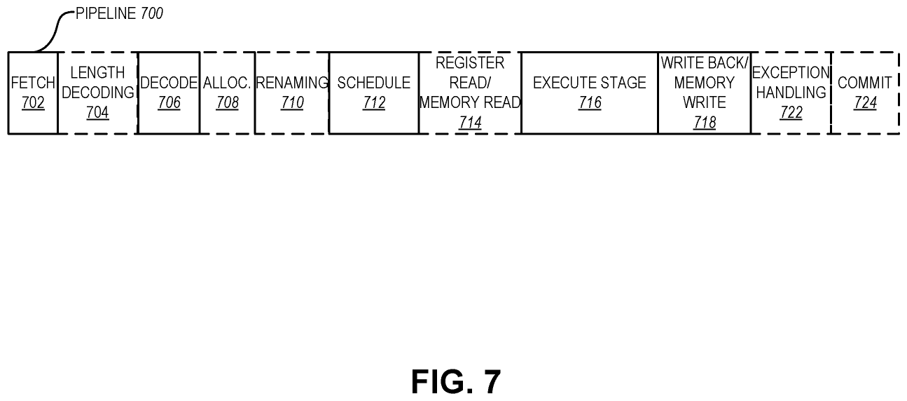

FIG. 7 is a block diagram illustrating both an example in-order pipeline 700 and an example register renaming, out-of-order issue/execution pipeline in accordance with some embodiments;

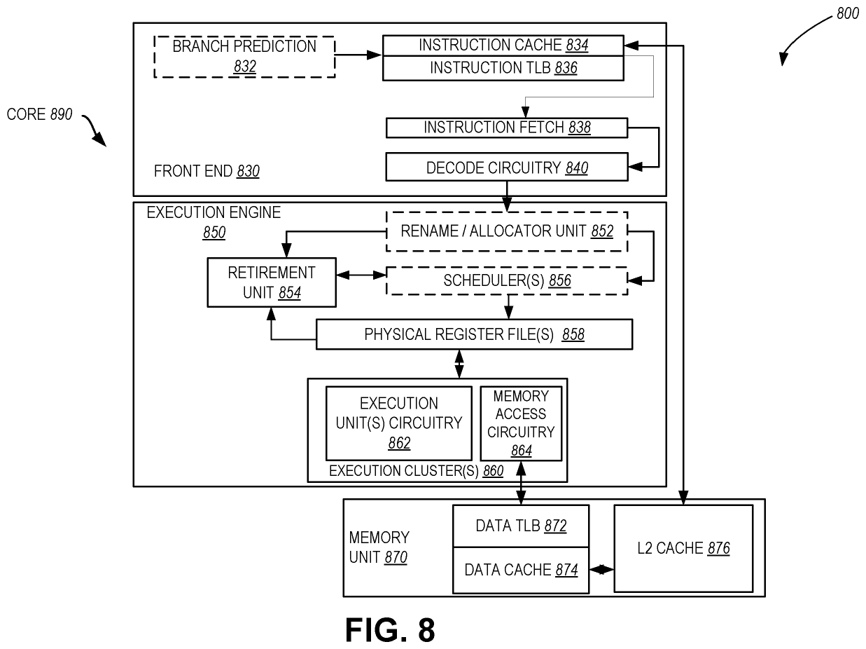

FIG. 8 is a block diagram 800 illustrating both an example in-order architecture core and an example register renaming, out-of-order issue/execution architecture core to be included in a processor in accordance with some embodiments;

The solid lined boxes in FIGS. 7-8 illustrate the in-order pipeline and in-order core, while the optional addition of the dashed lined boxes illustrates the register renaming, out-of-order issue/execution pipeline, and core. Given that the in-order aspect is a subset of the out-of-order aspect, the out-of-order aspect will be described.

In FIG. 7, a processor pipeline 700 includes a fetch stage 702, an optional length decoding stage 704, a decode stage 706, an optional allocation (Alloc) stage 708, an optional renaming stage 710, a schedule (also known as a dispatch or issue) stage 712, an optional register read/memory read stage 714, an execute stage 716, a write-back/memory write stage 718, an optional exception-handling stage 722, and an optional commit stage 724. One or more operations can be performed in each of these processor pipeline stages. For example, during the fetch stage 702, one or more instructions are fetched from instruction memory, and during the decode stage 706, the one or more fetched instructions may be decoded, addresses (e.g., load store unit (LSU) addresses) using forwarded register ports may be generated, and branch forwarding (e.g., immediate offset or a link register (LR)) may be performed. In one example, the decode stage 706 and the register read/memory read stage 714 may be combined into one pipeline stage. In one example, during the execute stage 716, the decoded instructions may be executed, LSU address/data pipelining to an Advanced Microcontroller Bus (AMB) interface may be performed, multiply and add operations may be performed, arithmetic operations with branch results may be performed, etc.

By way of example, the example register renaming, out-of-order issue/execution architecture core of FIG. 8 may implement the pipeline 700 as follows: 1) the instruction fetch circuitry 838 performs the fetch and length decoding stages 702 and 704; 2) the decode circuitry 840 performs the decode stage 706; 3) the rename/allocator unit circuitry 852 performs the allocation stage 708 and renaming stage 710; 4) the scheduler(s) circuitry 856 performs the schedule stage 712; 5) the physical register file(s) circuitry 858 and the memory unit circuitry 870 perform the register read/memory read stage 714; the execution cluster(s) 860 perform the execute stage 716; 6) the memory unit circuitry 870 and the physical register file(s) circuitry 858 perform the write back/memory write stage 718; 7) various circuitry may be involved in the exception handling stage 722; and 8) the retirement unit circuitry 854 and the physical register file(s) circuitry 858 perform the commit stage 724.

FIG. 8 shows a processor core 890 including front-end unit circuitry 830 coupled to execution engine unit circuitry 850, and both are coupled to memory unit circuitry 870. The core 890 may be a reduced instruction set architecture computing (RISC) core, a complex instruction set architecture computing (CISC) core, a very long instruction word (VLIW) core, or a hybrid or alternative core type. As yet another option, the core 890 may be a special-purpose core, such as, for example, a network or communication core, compression engine, coprocessor core, general-purpose computing graphics processing unit (GPGPU) core, graphics core, or the like.

The front-end unit circuitry 830 may include branch prediction circuitry 832 coupled to instruction cache circuitry 834, which is coupled to an instruction translation lookaside buffer (TLB) 836, which is coupled to an instruction fetch circuitry 838, which is coupled to decode circuitry 840. In one example, the instruction cache circuitry 834 is included in the memory unit circuitry 870 rather than the front-end circuitry 830. The decode circuitry 840 (or decoder) may decode instructions, and generate as an output one or more micro-operations, micro-code entry points, microinstructions, other instructions, or other control signals, which are decoded from, or which otherwise reflect, or are derived from, the original instructions. The decode circuitry 840 may further include address generation unit (AGU, not shown) circuitry. In one example, the AGU generates an LSU address using forwarded register ports, and may further perform branch forwarding (e.g., immediate offset branch forwarding, LR register branch forwarding, etc.). The decode circuitry 840 may be implemented using different mechanisms. Examples of suitable mechanisms include, but are not limited to, look-up tables, hardware implementations, programmable logic arrays (PLAs), microcode read-only memories (ROMs), etc. In one example, the core 890 includes a microcode ROM (not shown) or another medium that stores microcode for certain macroinstructions (e.g., in decode circuitry 840 or otherwise within the front-end circuitry 830). In one example, the decode circuitry 840 includes a micro-operation (micro-op) or operation cache (not shown) to hold/cache decoded operations, micro-tags, or micro-operations generated during the decode or other stages of the processor pipeline 700. The decode circuitry 840 may be coupled to rename/allocator unit circuitry 852 in the execution engine circuitry 850.

The execution engine circuitry 850 includes the rename/allocator unit circuitry 852 coupled to retirement unit circuitry 854 and a set of one or more scheduler(s) circuitry 856. The scheduler(s) circuitry 856 represents any number of different schedulers, including reservations stations, central instruction window, etc. In some examples, the scheduler(s) circuitry 856 can include arithmetic logic unit (ALU) scheduler/scheduling circuitry, ALU queues, address generation unit (AGU) scheduler/scheduling circuitry, AGU queues, etc. The scheduler(s) circuitry 856 is coupled to the physical register file(s) circuitry 858. Each of the physical register file(s) circuitry 858 represents one or more physical register files, different ones of which store one or more different data types, such as scalar integer, scalar floating-point, packed integer, packed floating-point, vector integer, vector floating-point, status (e.g., an instruction pointer that is the address of the next instruction to be executed), etc. In one example, the physical register file(s) circuitry 858 includes vector registers unit circuitry, write mask registers unit circuitry, and scalar register unit circuitry. These register units may provide architectural vector registers, vector mask registers, general-purpose registers, etc. The physical register file(s) circuitry 858 is coupled to the retirement unit circuitry 854 (also known as a retire queue or a retirement queue) to illustrate various ways in which register renaming and out-of-order execution may be implemented (e.g., using a reorder buffer(s) (ROB(s)) and a retirement register file(s); using a future file(s), a history buffer(s), and a retirement register file(s); using a register map and a pool of registers; etc.). The retirement unit circuitry 854 and the physical register file(s) circuitry 858 are coupled to the execution cluster(s) 860. The execution cluster(s) 860 includes a set of one or more execution unit(s) circuitry 862 and a set of one or more memory access circuitry 864. The execution unit(s) circuitry 862 may perform various arithmetic, logic, floating-point, or other types of operations (e.g., shifts, addition, subtraction, multiplication) and on various types of data (e.g., scalar integer, scalar floating-point, packed integer, packed floating-point, vector integer, vector floating-point). While some examples may include several execution units or execution unit circuitry dedicated to specific functions or sets of functions, other examples may include only one execution unit circuitry or multiple execution units/execution unit circuitry that perform all functions. The scheduler(s) circuitry 856, physical register file(s) circuitry 858, and execution cluster(s) 860 are shown as being possibly plural because certain examples create separate pipelines for certain types of data/operations (e.g., a scalar integer pipeline, a scalar floating-point/packed integer/packed floating-point/vector integer/vector floating-point pipeline, and/or a memory access pipeline that each has their scheduler circuitry, physical register file(s) circuitry, and/or execution cluster—and in the case of a separate memory access pipeline, certain examples are implemented in which only the execution cluster of this pipeline has the memory access unit(s) circuitry 864). It should also be understood that where separate pipelines are used, one or more of these pipelines may be out-of-order issue/execution and the rest in-order.

In some examples, the execution engine unit circuitry 850 may perform load store unit (LSU) address/data pipelining to an Advanced Microcontroller Bus (AMB) interface (not shown), and address phase and writeback, data phase load, store, and branches.

The set of memory access circuitry 864 is coupled to the memory unit circuitry 870, which includes data TLB circuitry 872 coupled to data cache circuitry 874 coupled to level 2 (L2) cache circuitry 876. In one example, the memory access circuitry 864 may include load unit circuitry, a store address unit circuitry, and store data unit circuitry, each of which is coupled to the data TLB circuitry 872 in the memory unit circuitry 870. The instruction cache circuitry 834 is further coupled to the level 2 (L2) cache circuitry 876 in the memory unit circuitry 870. In one example, the instruction cache circuitry 834 and the data cache circuitry 874 are combined into a single instruction and data cache (not shown) in L2 cache circuitry 876, level 3 (L3) cache circuitry (not shown), and/or main memory. The L2 cache circuitry 876 is coupled to one or more other levels of cache and eventually to the main memory.

The core 890 may support one or more instructions sets (e.g., the x86 instruction set architecture (optionally with some extensions that have been added with newer versions); the MIPS instruction set architecture; the ARM instruction set architecture (optionally with optional additional extensions such as NEON)), including the instruction(s) described herein. In one example, the core 890 includes logic to support a packed data instruction set architecture extension (e.g., AVX1, AVX2), thereby allowing the operations used by many multimedia applications to be performed using packed data.

In some embodiments, the memory devices discussed in connection with FIGS. 5-8 can be configured (including tested) using the disclosed techniques (e.g., as discussed in connection with FIGS. 9-24).

FIG. 9 is a block diagram of sequential timing test bench circuitry 900, in accordance with some embodiments. Referring to FIG. 9, the sequential timing test bench circuitry 900 includes a data delay generator (DDG) 906, a clock delay generator (CDG) 908, a reference delay generator (RDG) 910, a local tile 902, an output multiplexer (MUX) 912, and a capture flip-flop circuitry (FF) 904. The local tile 902 includes a device-under-test (DUT) 916 (e.g., a flip-flop or another device), and MUX 918.

DDG 906, CDG 9008, and RDG 910 receive one of the input signals 914 (which may include a data input signal din, a clock input signal clkin, and a reference input signal refin). DDG 906 comprises suitable circuitry, logic, interfaces, or code, and is configured to delay the data input signal din and provide the delayed data input signal to the MUX 918 and the data input port of the DUT 916.

CDG 908 comprises suitable circuitry, logic, interfaces, or code, and is configured to delay the clock input signal clkin and provide the delayed clock input signal to the MUX 918 and the clock port of the DUT 916.

RDG 910 comprises suitable circuitry, logic, interfaces, or code, and is configured to delay the reference input signal refin and provide the delayed reference input signal to the clock port of the capture FF 904.

DDG 906 and CDG 908 generate a variable data-to-clock delay. The 3-input MUX 918 selects among the data input (d), the clock input (clk), and the output (q) of DUT 916 to be measured. RDG 910 generates a variable delay (trdg) to measure the path delays which act as a clock for the capture FF 904. The capture FF 904 captures the signal transition which is being measured. The trdg delay, which the capture FF 904 captures, can be measured using the following equations:

$$trdg , d = td + tmux , d + txor , d + toutmux , d + tcff , d ( data delay ) ; \qquad ( a )$$

$$trdg , ck = tck + tmux , \text{} ck + txor , \text{} ck + toutmux , \text{} ck + tcff , \text{} ck ( clk delay ) ; and \qquad ( b )$$

$$trdg , q = tq + tmux , q + txor , q + toutmux , q + tcff , q ( output delay ) . \qquad ( c )$$

The setup and clock-to-output (clk2q) delays can be calculated using the following equations:

$$trdg , ck - trdg , d = ( tck - td ) + Δ tmux + Δ txor + Δ toutmux + Δ tcff ; and \qquad ( a )$$

$$trdg , q - trdg , ck = ( tq - tck ) + Δ tmux + Δ txor + Δ toutmux + Δ tcff . \qquad ( b )$$

Delay values td, tq, tck, tmux, toutmax, trdg, and toff are indicated in FIG. 9. In some aspects, Δtmux, Δtxor=
0 (desigened for symmetric rise & fall delay), and Δtoutmux, Δcff=
0 (only rising edge propogation).

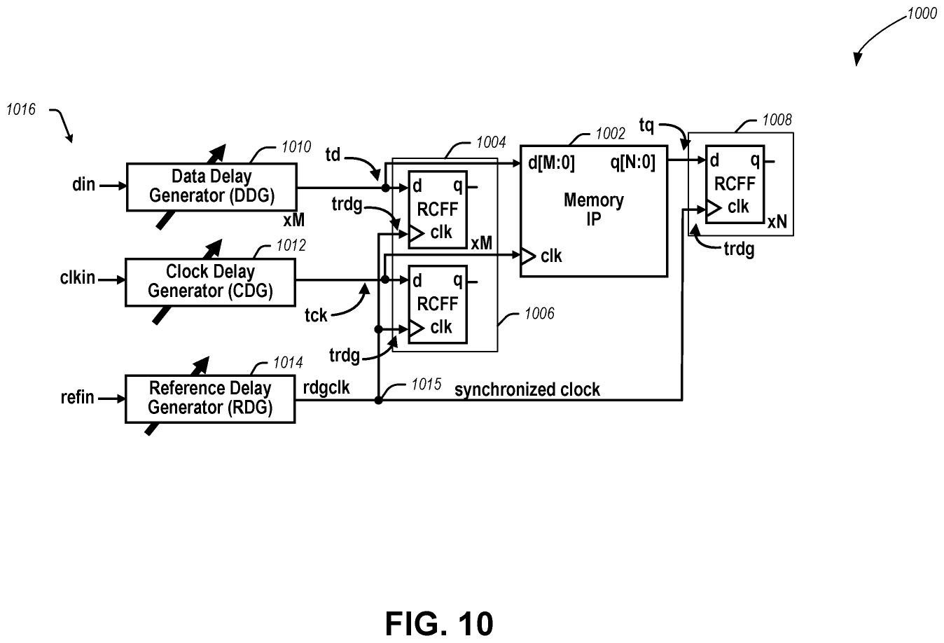

FIG. 10 is a block diagram of memory IP timing test bench circuitry 1000, in accordance with some embodiments. The memory IP timing test bench circuitry 1000 includes DDG 1010, CDG 1012, RDG 1014, DUT 1002 (e.g., a memory IP), and RCFFs 1004, 1006, and 1008

DDG 1010, CDG 1012, and RDG 1014 receive one of the input signals 1016 (which includes a data input signal din, a clock input signal clkin, and a reference input signal refin). DDG 1010 comprises suitable circuitry, logic, interfaces, or code, and is configured to delay the data input signal din and provide the delayed data input signal to the data terminals (d) of RCFF 1004 and DUT 1002.

CDG 1012 comprises suitable circuitry, logic, interfaces, or code, and is configured to delay the clock input signal clkin and provide the delayed clock input signal to the data terminals (d) of RCFF 1006 and the clock terminal (clk) of DUT 1002.

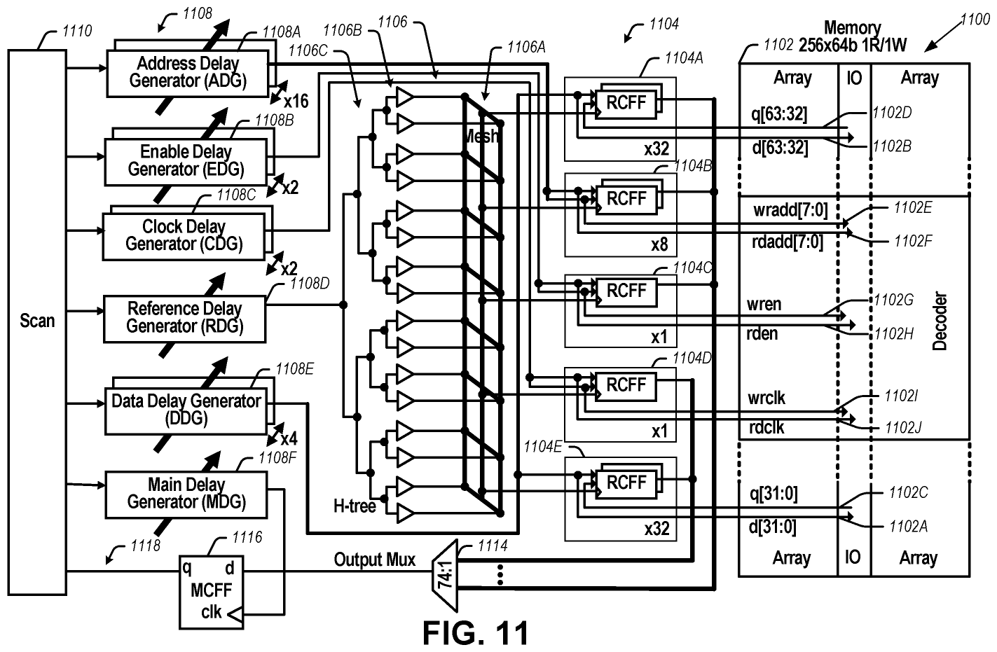

RDG 1014 comprises suitable circuitry, logic, interfaces, or code, and is configured to delay the reference input signal refin and provide the delayed reference input signal (e.g., a synchronized clock signal rdgclk) to the clock terminals of RCFFs 1004, 1006, and 1008. RDG 1014 includes an output node 1015, which is coupled (e.g., directly coupled or coupled via a clock mesh as illustrated in FIG. 11) to the clock inputs of the RCFFs associated with the device-under-test (e.g., RCFFs 1004, 1006, and 1008).

Since memory IPs have multiple inputs/outputs whose physical locations are not in close-proximity, the capture FF in the sequential test-bench is replicated and placed close to the memory I/O physical location as an RCFF (as illustrated in FIG. 10). RCFFs 1004-1008 are driven by a synchronized variable delay clock signal (rdgclk). Each input to the memory IP (e.g., DUT 1002) is connected to a variable delay generator and is also captured by its own RCFF. The setup and clk2q delays of DUT 1002 are calculated using the following equations:

$$trdg , ck - trdg , d = ( tck - td ) + Δtrdgclk\_skew + Δtrcff\_setup ; and \qquad ( a )$$

$$trdg , q - trdg , ck = ( tq - tck ) + Δtrdgclk\_skew + Δtrcff\_setup . \qquad ( b )$$

In the above equations, Atrdgclk_skew is RCFFs clock (rdgclk) skew and Atrcff_setup is the RCFFs setup difference due to rise/fall, physical location and PVT.

FIG. 11 is a block diagram of memory IP timing characterization circuitry 1100 with multiple delay generators, in accordance with some embodiments. Referring to FIG. 11, the memory IP timing characterization circuitry 1100 includes a scan signal generator 1110 (also referred to as a reference signal generator), a plurality of delay generators 1108, a main capture flip-flop (or MCFF) 1116, an output MUX 1114, a clock mesh 1106, a plurality of flip-flop circuits (or RCFFs) 1104, and a DUT 1102 (e.g., a memory device). DUT 1102 includes data ports (d) 1102A and 1102B, output ports (or outputs) (q) 1102C and 1102D, a write address port (wradd) 1102E, a read address port (rdadd) 1102F, a write enable port (wren) 1102G, a read enable port (rden) 1102H, a write clock port (wrclk) 1102I, and a read clock port (rdclk) 1102J. The plurality of RCFFs 1104 includes RCFFs 1104A, 1104B, 1104C, 1104D, and 1104E. Each of the RCFFs 1104A, 1104B, 1104C, 1104D, and 1104E can include multiple RCFFs (e.g., as indicated by x1, x8, and x32 in FIG. 11).

In some embodiments, clock mesh 1106 can be configured to reduce clock skew across the plurality of RCFFs 1104. Clock mesh 1106 includes a plurality of symmetric clock input buffers 1106B connected via an H-tree network (or H-tree) 1106C. The outputs of the plurality of symmetric clock input buffers 1106B are coupled to the plurality of RCFFs 1104 via a mesh (or mesh network) 1106A.

The plurality of delay generators 1108 includes at least one address delay generator (ADG) 1108A, at least one enable delay generator (EDG) 1108B, at least one clock delay generator (CDG) 1108C, a reference delay generator (RDG) 1108D, at least one data delay generator (DDG) 1108E, and a main delay generator (MDG) 1108F.

In some aspects, the test bench of FIG. 11 characterizes a 256x64b 1R/1 W ported dynamic register file memory as the DUT 1102. The short delay generators (ADG 1108A, EDG 1108B, CDG 1108C, and DDG 1108E) feed the address, enable, clock and data inputs of the DUT 1102, while the medium delay generator (RDG 1108D) drives the clock input of the plurality of RCFFs 1104.

The long delay generator (MDG 1108F) is used as a variable delay clock for the final MCFF 1116, which characterizes the setup time of the plurality of RCFFs 1104. More specifically, the outputs of the plurality of RCFFs 1104 are communicated via signal path 1118 to output MUX 1114 and MCFF 1116. The output of MCFF 1116 is received by the scan signal generator 1110 and is used to adjust the delays of one or more of the plurality of delay generators 1108. In this regard, the MCFF 1116 acts as a capture FF as shown in the sequential testbench circuit of FIG. 9 and is used to characterize the setup time of RCFFs. This setup time differences (Δtrcff_setup skew in the above equations) across RCFFs due to physical locality and PVT is added/subtracted to compensate for measurement errors while capturing input/outputs of DUT 1102.

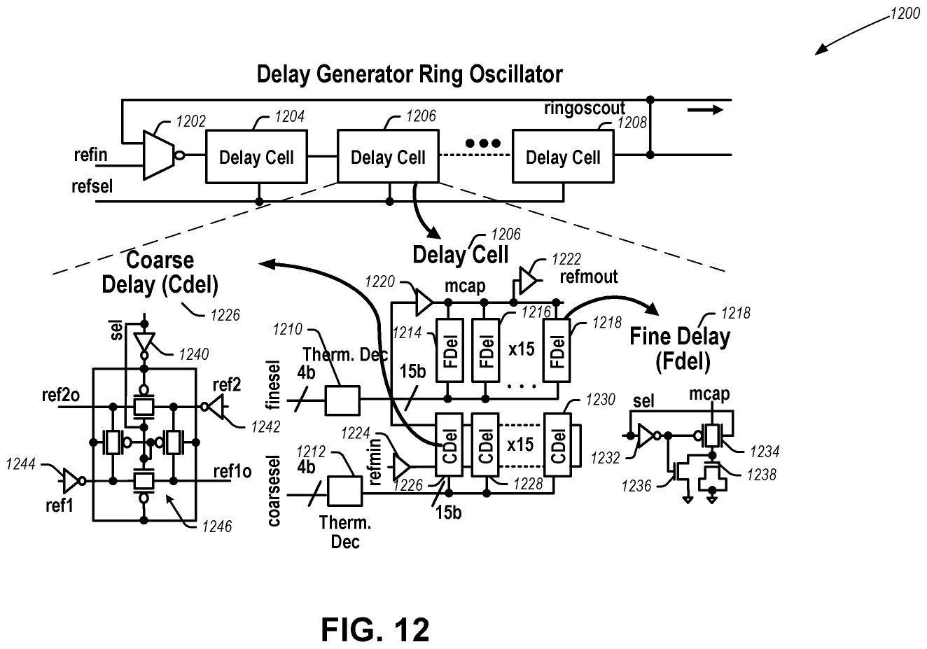

FIG. 12 is a block diagram of a delay generator circuit 1200, in accordance with some embodiments. The delay generator circuit 1200 (also referred to as a delay generator 1200) can be any of the delay generators discussed in connection with FIG. 9-FIG. 11. Referring to FIG. 12, delay generator 1200 includes a MUX 1202 and a plurality of delay cells 1204, 1206, . . . , 1208. In some aspects, a delay cell (e.g., delay cell 1206) includes thermometer decoder circuits 1210 and 1212, inverters 1220, 1222, and 1224, coarse delay elements (Cdel) 1226, 1228, . . . , 1230, and fine delay elements (Fdel) 1214, 1216, . . . , 1218.

In some aspects, an example Cdel 1226 includes inverters 1240, 1242, and 1244, and a plurality of transmission gates 1246. In some aspects, an example Fdel 1218 includes an inverter 1232, a transmission gate 1234, and transistors 1236 and 1238.

In some aspects, delay generator 1200 can be designed using delay cells containing 15 mux-ladder-based coarse delay elements (e.g., Cdel 1226, . . . 1230) and 15 gate-cap-based fine delay elements (e.g., Fdel 1214, . . . , 1218), selected by 4-bit thermometer decoders (e.g., thermometer decoder circuits 1210 and 1212) for monotonic delay (e.g., as illustrated in FIG. 12).

In some aspects, a delay cell is characterized by measuring the ring oscillator frequency across all delay configurations. Saturation bits can be computed to eliminate delay overlap between coarse and fine delay settings, enabling a monotonic delay.

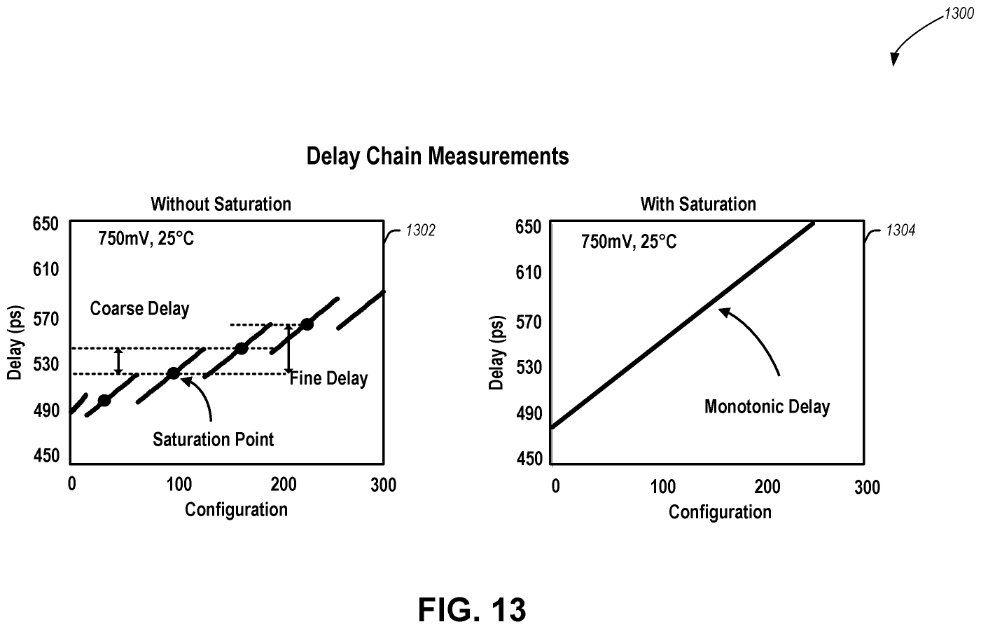

FIG. 13 is a diagram 1300 of delay chain measurements for the delay generator circuit of FIG. 12, in accordance with some embodiments. Referring to FIG. 13, graph 1302 illustrates delay chain measurements without saturation and graph 1304 illustrates delay chain measurements with saturation. More specifically, FIG. 13 illustrates measurements at 750 mV and 25° C. show ˜20ps/˜0.7ps resolution across coarse/fine delay settings, respectively.

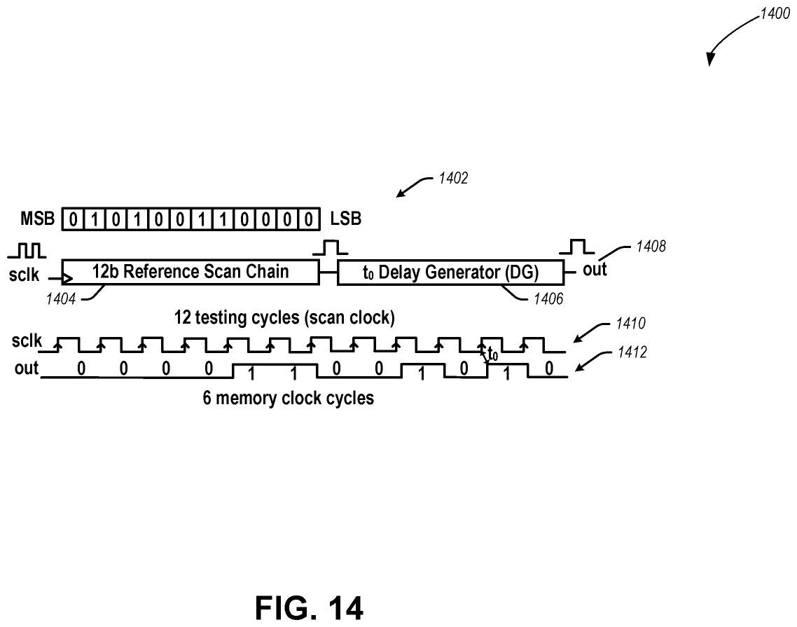

FIG. 14 is diagram 1400 of a reference scan chain for 12 testing and 6 memory execution clock cycles for the delay generator circuit of FIG. 12, in accordance with some embodiments. In some aspects, 12-bit parallel reference scan chains provide the triggering edge input to all the delay generators for 12 consecutive testing cycles (scan clock). The outputs of these delay generators provide memory inputs, resulting in 6 memory clock cycles execution capabilities. FIG. 14 illustrates an example scan chain 1404 input to delay generator 1406 to generate output signal 1408. Reference scan chain 1404 can be generated by scan signal generator 1110 and can include bit arrangement 1402. Reference scan chain 1404 can be used to configure a plurality of testing cycles 1410 (e.g., 12 testing cycles) and a plurality of memory clock cycles 1412 (e.g., 6 memory clock cycles).

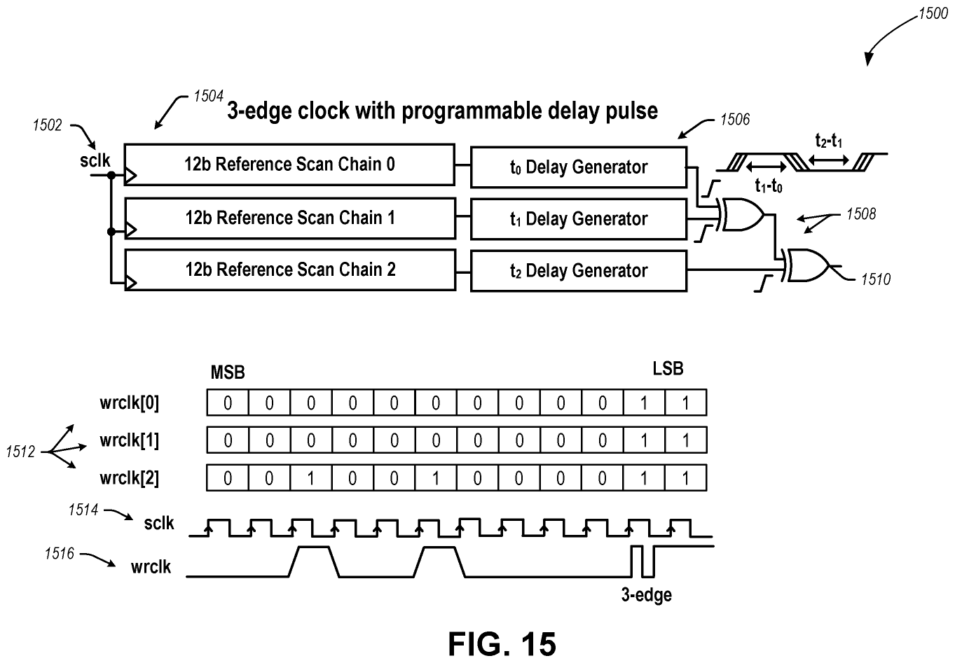

FIG. 15 is a diagram 1500 of reference scan chains for a 3-edge clock/enable generation circuit with a programmable delay pulse, in accordance with some embodiments. In some aspects, the clocks to the memory IP can be derived using 3 variable short delay generators 1506 with a series of XOR gates 1508 (e.g., as used in a CDG) to generate signal output 1510 using multiple reference scan chains 1504 associated with an input clock signal 1502. Based on programmable scan chains and variable delays (t0-t2), the clocks in a given testing cycle (e.g., clock signals 1512) can be configured as a single edge (e.g., clock diagram 1514) or up to 3-edge clock (e.g., clock diagram 1516) with programmable delay pulse. A similar scheme is implemented for write and read enable signals (e.g., as used in an EDG), providing high-resolution setup, cycle time, and read-after-write delay measurements.

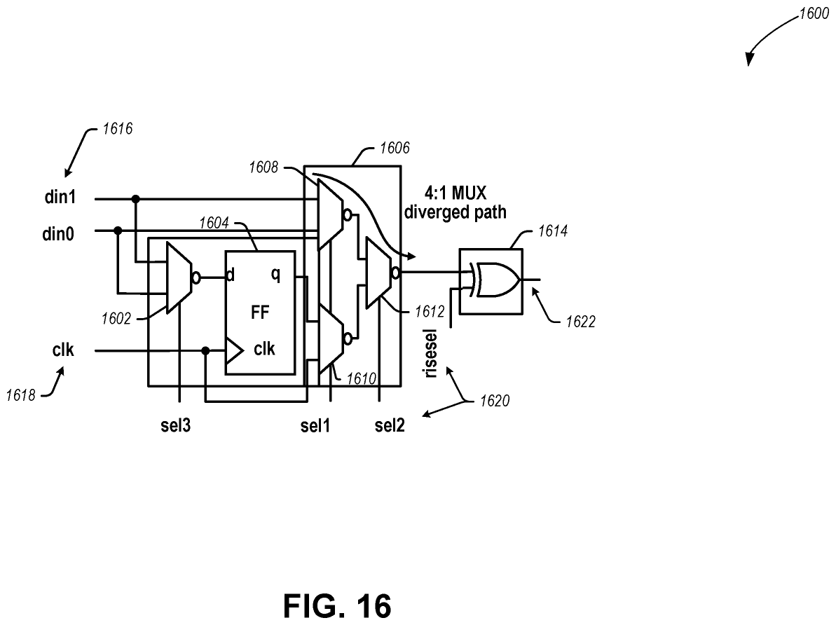

FIG. 16 is a block diagram of a regional capture flip-flop (RCFF) 1600 with a rising select XOR gate, in accordance with some embodiments. Referring to FIG. 16, RCFF 1600 can be used in any of the disclosed configurations. In some aspects, RCFF 1600 includes a MUX 1602, a flip-flop circuit 1604, an inverting symmetric MUX tree 1606, and an XOR gate 1614 (e.g., a rising select XOR).

In some aspects, RCFF 1600 can capture two inputs 1616, and a clock input signal 1618, and perform signal processing based on select signals 1620 to generate output signal 1622. Mux tree 1606 can include MUXs 1608, 1610, and 1612 to configure a two-gate stage diverged path for each input, minimizing measurement error. The rising select XOR 1614 converts falling edges into rising edges with symmetrical delay switching across PVT. This enables only rising edge injection to the output MUX delay path, removing measurement error due to delay propagation and MCFF setup time mismatch between rising/falling edges.

In some embodiments, RCFF's clock input signal 1618 is connected to a low-skew clock tree mesh, which is driven by symmetrically placed multiple clock mesh buffers. The inputs of these clock buffers are connected through an H-tree and a fishbone routing is performed to connect the RCFF's clock pin to the clock mesh resulting in sub-ps skew. The RCFF uses this low-skew variable delay clock to capture and characterize setup/hold/clk-q timing of memory IP (Δtrdgclk_skew≈0).

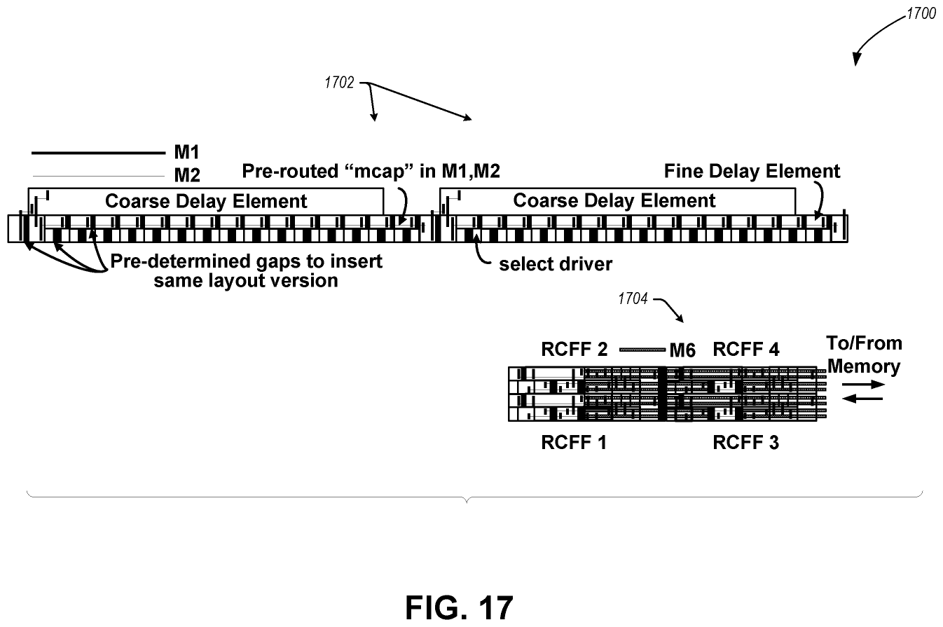

FIG. 17 is a diagram 1700 of relative placement and pre-routing of delay cells and RCFFs to minimize measurement errors due to layout/routing mismatch, in accordance with some embodiments. Referring to FIG. 17, diagram 1700 illustrates the placement and pre-routing 1702 of delay cells, and the placement and pre-routing 1704 of RCFFs.

In some aspects, the synthesis scripts are fully reconfigurable to accept memory IPs of varying sizes and configurations. Relative placement and custom pre-routing commands are used for the critical circuits to improve layout/routing quality. The physical design scripts can be implemented to enable matched layout/routing for all the delay generators and RCFFs independent of the memory IP under test (e.g., as illustrated in FIG. 17). More specifically, RCFFs are structurally placed in columns at the edge of the memory IP based on the input/output port physical location. Pre-determined gaps are inserted between layout cells to infer the same layout version across all the instantiations. These semi-automated optimizations along with low skew clock mesh reduce measurement errors due to layout/routing mismatch and physical proximity difference of memory IP I/Os.

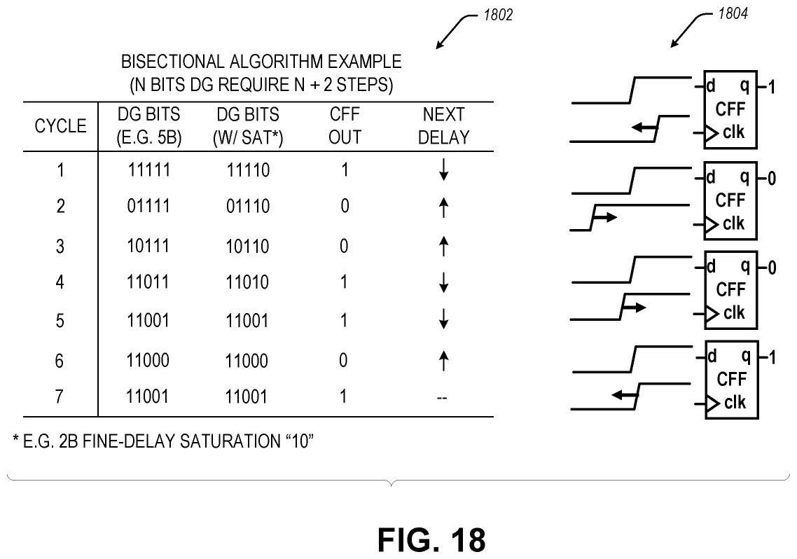

FIG. 18 illustrates table 1802 with a bisectional algorithm example, in accordance with some embodiments. FIG. 18 further illustrates a corresponding timing diagram 1804 of CFF signal timing based on table 1802.

In some aspects, bisectional algorithm-based testing is implemented for fast test time and the capability of testing different timing parameters by using an I/O scan only. This bisectional algorithm implements a binary sweep (e.g., table 1802) to calculate timing parameters with n+2 steps instead of a traditional linear sweep with 2″ steps, where n is the number of delay generator configuration bits (e.g. 12-bit for 5 delay cell-based short delay generator).

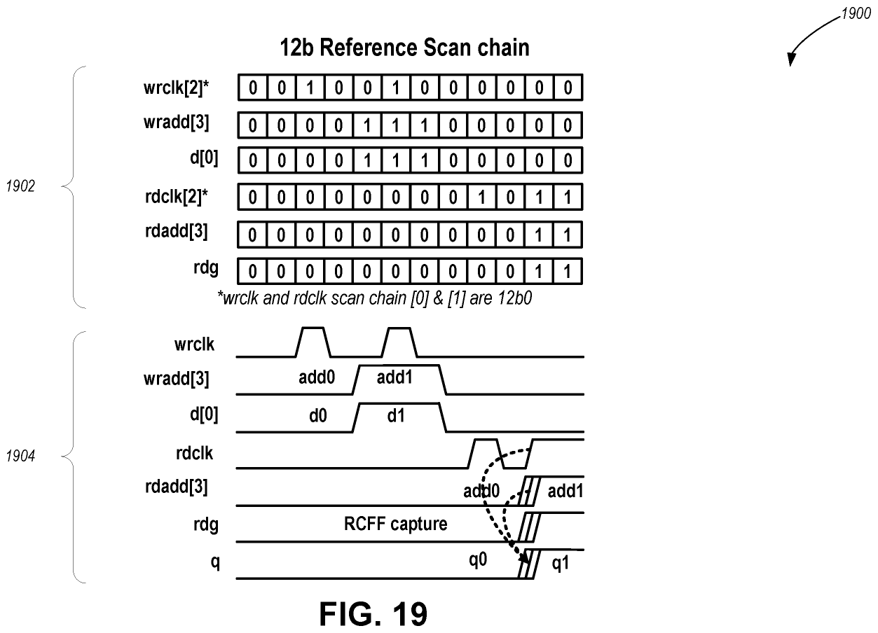

FIG. 19 illustrates a diagram 1900 of clk2q and read address setup time characterization methodology, in accordance with some embodiments. More specifically, FIG. 19 illustrates example 12-bit reference scan chains 1902 and corresponding signal timing diagrams 1904.

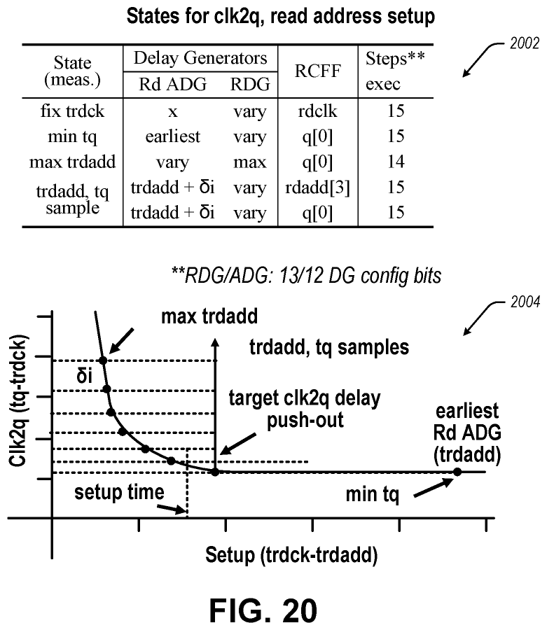

FIG. 20 illustrates states 2002 for clk2q and read address setup for the time characterization methodology of FIG. 19, in accordance with some embodiments. FIG. 20 further illustrates a graph 2004 of setup vs. clk2q timing curve.

More specifically, FIGS. 19-20 show example steps for measuring clk2q and read address setup time. For the rising setup, the measured address bit (rdadd[3]) is switched from 0 to 1, while the rest of the address bits are kept constant in a given state. A 0 input data is written to wradd[3] when it is equal to 0, and 1 is written to wradd[3] when it is equal to 1. Following this, the data is read sequentially from both locations, creating a rising transition in the memory outputs. The address, output, and memory clock transitions are captured following the methodology described in the above equations to sample the setup vs. clk2q timing curve. Setup delay is extracted from the timing curve with a target delay push-out from minimum clk2q delay. This is repeated for all address input combinations for address/data rising and falling pairs.

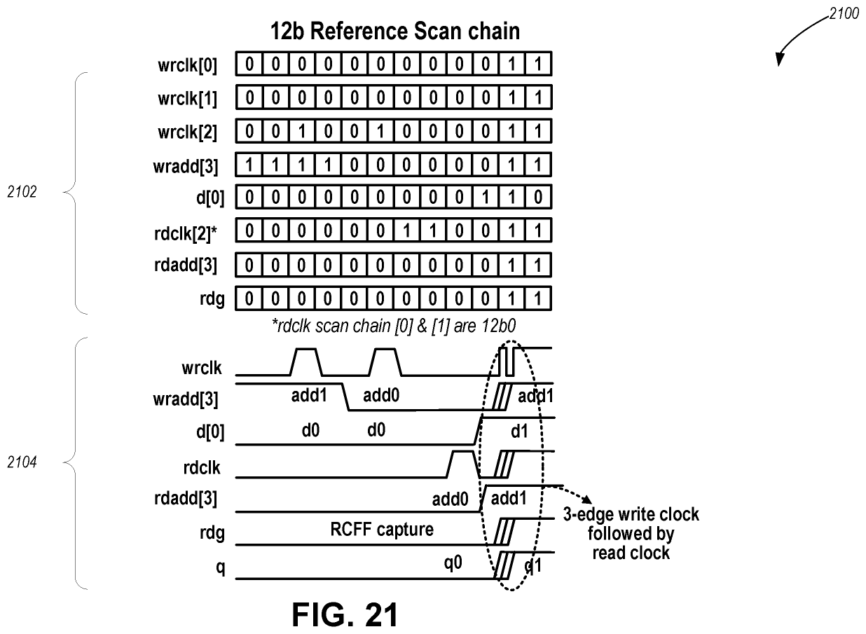

FIG. 21 illustrates a diagram 2100 of write address setup and write-cycle-time characterization methodology, in accordance with some embodiments. More specifically, FIG. 21 illustrates example 12-bit reference scan chains 2102 and corresponding signal timing diagrams 2104.

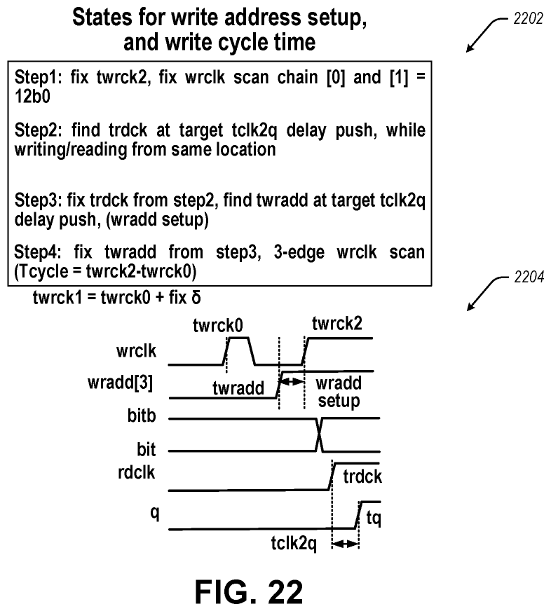

FIG. 22 illustrates states 2202 for write address setup and write cycle time for the time characterization methodology of FIG. 21 and a corresponding timing diagram 2204, in accordance with some embodiments.

FIGS. 21-22 show example steps for measuring write address setup and write-cycle-time. Unlike the read address setup, 0 input data is written to both address locations. The test is performed by writing 1 when wradd[3] transitions to 1, while simultaneously reading from the same location. The read clock delay is varied to find the delay setting where the read delay after the write has a target delay push-out from minimum read clk2q. The read clock is fixed at this delay setting. Write address delay is then increased to sample write setup vs. read clk2q curve, to extract the write setup delay. A write-cycle-time measurement is set up by providing a 3-edge write clock while fixing the read clock and write address delays as in the write address setup measurement. Write-cycle-time is extracted from cycle time vs. read clk2q curve by varying the delay between two rising edges of the 3-edge write clock.

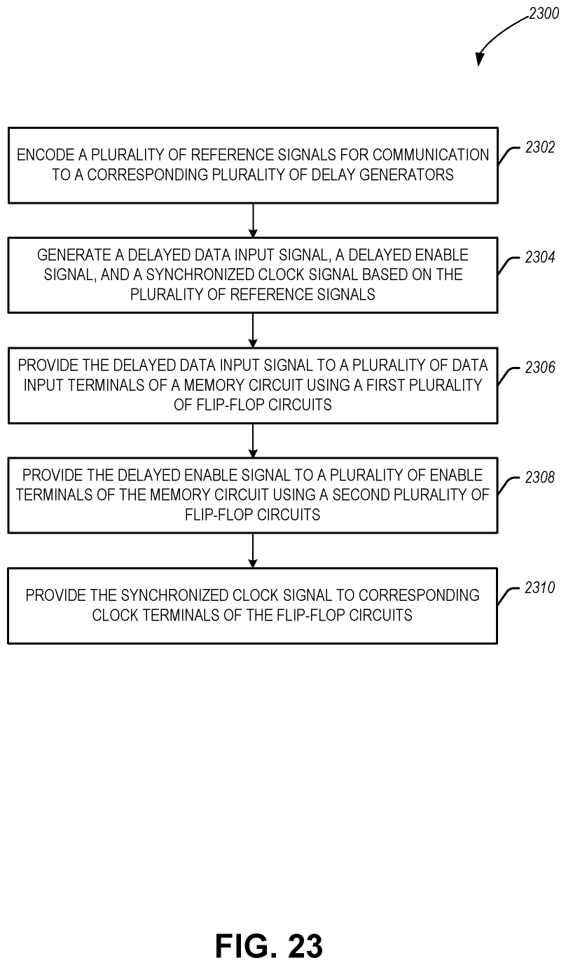

FIG. 23 is a flow diagram of an example method for memory timing characterization, in accordance with some embodiments. Referring to FIG. 23, method 2300 includes operations 2302, 2304, 2306, 2308, and 2310, which may be executed by a memory configuration circuit or another processor of a computing device (e.g., hardware processor 2402 of device 2400 illustrated in FIG. 24).

At operation 2302, a plurality of reference signals (e.g., as generated by the scan signal generator 1110) are encoded for communication to a corresponding plurality of delay generators (e.g., the plurality of delay generators 1108).

At operation 2304, a delayed data input signal, a delayed enable signal, and a synchronized clock signal are generated based on the plurality of reference signals. For example, a delayed data input signal is generated by DDG 1108E, a delayed enable signal is generated by EDG 1108B, and a synchronized clock signal is generated by RDG 1108D.

At operation 2306, the delayed data input signal is provided to a plurality of data input terminals of a memory circuit (e.g., DUT 1102) using a first plurality of flip-flop circuits (e.g., RCFFs 1104A and 1104E).

At operation 2308, the delayed enable signal is provided to a plurality of enable terminals (e.g., enable terminals 1102G and 1102H) of the memory circuit using a second plurality of flip-flop circuits (e.g., RCFFs 1104C).

At operation 2310, the synchronized clock signal is provided (e.g., via clock mesh 1106) to corresponding clock terminals of the first plurality of flip-flop circuits and the second plurality of flip-flop circuits.

FIG. 24 illustrates a block diagram of an example machine 2400 upon which any one or more of the techniques (e.g., methodologies) discussed herein may perform. In alternative embodiments, the machine 2400 may operate as a standalone device or may be connected (e.g., networked) to other machines. In a networked deployment, machine 2400 may operate in the capacity of a server machine, a client machine, or both in server-client network environments. In an example, machine 2400 may act as a peer machine in a peer-to-peer (P2P) (or other distributed) network environment. The machine 2400 may be a personal computer (PC), a tablet PC, a set-top box (STB), a personal digital assistant (PDA), a portable communications device, a mobile telephone, a smartphone, a web appliance, a network router, switch or bridge, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Machine (e.g., computer system) 2400 may include a hardware processor 2402 (e.g., a central processing unit (CPU), a graphics processing unit (GPU), a hardware processor core, or any combination thereof), a main memory 2404, and a static memory 2406, some or all of which may communicate with each other via an interlink (e.g., bus) 2408. In some aspects, the main memory 2404, the static memory 2406, or any other type of memory (including cache memory) used by the machine 2400 can be configured based on the disclosed techniques or can implement the disclosed memory devices.

Specific examples of main memory 2404 include Random Access Memory (RAM), and semiconductor memory devices, which may include, in some embodiments, storage locations in semiconductors such as registers. Specific examples of static memory 2406 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; and CD-ROM and DVD-ROM disks.

Machine 2400 may further include a display device 2410, an input device 2412 (e.g., a keyboard), and a user interface (UI) navigation device 2414 (e.g., a mouse). In an example, the display device 2410, input device 2412, and UI navigation device 2414 may be a touch screen display. The machine 2400 may additionally include a storage device (e.g., drive unit or another mass storage device) 2416, a signal generation device 2418 (e.g., a speaker), a network interface device 2420, and one or more sensors 2421, such as a global positioning system (GPS) sensor, compass, accelerometer, or other sensors. The machine 2400 may include an output controller 2428, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.). In some embodiments, the processor 2402 and/or instructions 2424 may comprise processing circuitry and/or transceiver circuitry.

The storage device 2416 may include a machine-readable medium 2422 on which is stored one or more sets of data structures or instructions 2424 (e.g., software) embodying or utilized by any one or more of the techniques or functions described herein. The instructions 2424 may also reside, completely or at least partially, within the main memory 2404, within static memory 2406, or the hardware processor 2402 during execution thereof by the machine 2400. In an example, one or any combination of the hardware processor 2402, the main memory 2404, the static memory 2406, or the storage device 2416 may constitute machine-readable media.

Specific examples of machine-readable media may include non-volatile memory, such as semiconductor memory devices (e.g., EPROM or EEPROM) and flash memory devices; magnetic disks, such as internal hard disks and removable disks; magneto-optical disks; RAM; and CD-ROM and DVD-ROM disks.

While the machine-readable medium 2422 is illustrated as a single medium, the term “machine-readable medium” may include a single medium or multiple media (e.g., a centralized or distributed database, and/or associated caches and servers) configured to store one or more instructions 2424.

An apparatus of the machine 2400 may be one or more of a hardware processor 2402 (e.g., a central processing unit (CPU), a graphics processing unit (GPU), a hardware processor core, or any combination thereof), a main memory 2404 and a static memory 2406, one or more sensors 2421, a network interface device 2420, antennas 2460, a display device 2410, an input device 2412, a UI navigation device 2414, a storage device 2416, instructions 2424, a signal generation device 2418, and an output controller 2428. The apparatus may be configured to perform one or more of the methods and/or operations disclosed herein. The apparatus may be intended as a component of machine 2400 to perform one or more of the methods and/or operations disclosed herein, and/or to perform a portion of one or more of the methods and/or operations disclosed herein. In some embodiments, the apparatus may include a pin or other means to receive power. In some embodiments, the apparatus may include power conditioning hardware.

The term “machine-readable medium” may include any medium that is capable of storing, encoding, or carrying instructions for execution by the machine 2400 and that causes the machine 2400 to perform any one or more of the techniques of the present disclosure, or that is capable of storing, encoding or carrying data structures used by or associated with such instructions. Non-limiting machine-readable medium examples may include solid-state memories and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks. In some examples, machine-readable media may include non-transitory machine-readable media. In some examples, machine-readable media may include machine-readable media that is not a transitory propagating signal.

The instructions 2424 may further be transmitted or received over a communications network 2426 using a transmission medium via the network interface device 2420 utilizing any one of several transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®, IEEE 802.16 family of standards known as WiMax®), IEEE 802.15.4 family of standards, a Long Term Evolution (LTE) family of standards, a Universal Mobile Telecommunications System (UMTS) family of standards, peer-to-peer (P2P) networks, among others.

In an example, the network interface device 2420 may include one or more physical jacks (e.g., Ethernet, coaxial, or phone jacks) or one or more antennas to connect to the communications network 2426. In an example, the network interface device 2420 may include one or more antennas 2460 to wirelessly communicate using at least one single-input multiple-output (SIMO), multiple-input multiple-output (MIMO), or multiple-input single-output (MISO) techniques. In some examples, the network interface device 2420 may wirelessly communicate using Multiple User MIMO techniques. The term “transmission medium” shall be taken to include any intangible medium that is capable of storing, encoding, or carrying instructions for execution by the machine 2400, and includes digital or analog communications signals or other intangible media to facilitate communication of such software.

Examples, as described herein, may include, or may operate on, logic or several components, modules, or mechanisms. Modules are tangible entities (e.g., hardware) capable of performing specified operations and may be configured or arranged in a certain manner. In an example, circuits may be arranged (e.g., internally or concerning external entities such as other circuits) in a specified manner as a module. In an example, the whole or part of one or more computer systems (e.g., a standalone, client, or server computer system) or one or more hardware processors may be configured by firmware or software (e.g., instructions, an application portion, or an application) as a module that operates to perform specified operations. In an example, the software may reside on a machine-readable medium. In an example, the software, when executed by the underlying hardware of the module, causes the hardware to perform the specified operations.

Accordingly, the term “module” is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using the software, the general-purpose hardware processor may be configured as respective different modules at different times. The software may accordingly configure a hardware processor, for example, to constitute a particular module at one instance of time and to constitute a different module at a different instance of time.

Some embodiments may be implemented fully or partially in software and/or firmware. This software and/or firmware may take the form of instructions contained in or on a non-transitory computer-readable storage medium. Those instructions may then be read and executed by one or more processors to enable the performance of the operations described herein. The instructions may be in any suitable form, such as but not limited to source code, compiled code, interpreted code, executable code, static code, dynamic code, and the like. Such a computer-readable medium may include any tangible non-transitory medium for storing information in a form readable by one or more computers, such as but not limited to read-only memory (ROM); random access memory (RAM); magnetic disk storage media; optical storage media; flash memory, etc.

The above-detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof) or with respect to other examples (or one or more aspects thereof) shown or described herein.

Publications, patents, and patent documents referred to in this document are incorporated by reference herein in their entirety, as though individually incorporated by reference. In the event of inconsistent usage between this document and those documents so incorporated by reference, the usage in the incorporated reference(s) is supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels and are not intended to suggest a numerical order for their objects.

The embodiments as described above may be implemented in various hardware configurations that may include a processor for executing instructions that perform the techniques described. Such instructions may be contained in a machine-readable medium such as a suitable storage medium or a memory or other processor-executable medium.

The embodiments as described herein may be implemented in several environments such as part of a wireless local area network (WLAN), 3rd Generation Partnership Project (3GPP) Universal Terrestrial Radio Access Network (UTRAN), or Long-Term-Evolution (LTE) or a Long-Term-Evolution (LTE) communication system, although the scope of the disclosure is not limited in this respect.

Antennas referred to herein may comprise one or more directional or omnidirectional antennas, including, for example, dipole antennas, monopole antennas, patch antennas, loop antennas, microstrip antennas, or other types of antennas suitable for transmission of RF signals. In some embodiments, instead of two or more antennas, a single antenna with multiple apertures may be used. In these embodiments, each aperture may be considered a separate antenna. In some multiple-input multiple-output (MIMO) embodiments, antennas may be effectively separated to take advantage of spatial diversity and the different channel characteristics that may result between each antenna and the antennas of a transmitting station. In some MIMO embodiments, antennas may be separated by up to 1/10 of a wavelength or more.

Described implementations of the subject matter can include one or more features, alone or in combination as illustrated below by way of examples.

Example 1 is an apparatus comprising: a first flip-flop circuit coupled to a data input terminal of a memory circuit; a second flip-flop circuit coupled to a clock terminal of the memory circuit; a third flip-flop circuit coupled to an output terminal of the memory circuit; and a reference delay generator coupled to a clock terminal of the first flip-flop circuit, a clock terminal of the second flip-flop circuit, and a clock terminal of the third flip-flop circuit.

In Example 2, the subject matter of Example 1 includes, a data delay generator coupled to the first flip-flop circuit and the memory circuit, the data delay generator to receive a data input signal, and delay the data input signal to generate a delayed data input signal.

In Example 3, the subject matter of Example 2 includes subject matter where the data delay generator is to communicate the delayed data input signal to a data input terminal of the first flip-flop circuit and the data input terminal of the memory circuit.

In Example 4, the subject matter of Examples 1-3 includes a clock delay generator coupled to the second flip-flop circuit and the memory circuit, the clock delay generator to receive a memory clock signal, and delay the memory clock signal to generate a delayed memory clock signal.

In Example 5, the subject matter of Example 4 includes subject matter where the clock delay generator is to communicate the delayed memory clock signal to a data input terminal of the second flip-flop circuit and the clock terminal of the memory circuit.

In Example 6, the subject matter of Examples 1-5 includes subject matter where the output terminal of the memory circuit is coupled to a data input terminal of the third flip-flop circuit.

In Example 7, the subject matter of Examples 1-6 includes, a reference signal generator coupled to the reference delay generator, the reference delay generator to receive a reference signal generated by the reference signal generator, and delay the reference signal to generate a synchronized clock signal.

In Example 8, the subject matter of Example 7 includes, a clock mesh coupled to the reference delay generator, the clock terminal of the first flip-flop circuit, the clock terminal of the second flip-flop circuit, and the clock terminal of the third flip-flop circuit.

In Example 9, the subject matter of Example 8 includes, the clock mesh further comprising: a plurality of buffer pairs, and the plurality of buffer pairs coupled to the reference delay generator via an H-tree network.

In Example 10, the subject matter of Example 9 includes subject matter where the clock mesh is to receive the synchronized clock signal via the H-tree network, and supply the synchronized clock signal to the clock terminal of the first flip-flop circuit, the clock terminal of the second flip-flop circuit, and the clock terminal of the third flip-flop circuit.

Example 11 is an apparatus comprising: a plurality of delay generators comprising a data delay generator, an enable delay generator, and a reference delay generator; a first plurality of flip-flop circuits coupled to the data delay generator to receive a delayed data input signal, and provide the delayed data input signal to a plurality of data input terminals of a memory circuit; a second plurality of flip-flop circuits coupled to the enable delay generator to receive a delayed enable signal, and provide the delayed enable signal to a plurality of enable terminals of the memory circuit; a third plurality of flip-flop circuits coupled to an output terminal of the memory circuit; and the reference delay generator to provide a synchronized clock signal to corresponding clock terminals of the first plurality of flip-flop circuits, the second plurality of flip-flop circuits, and the third plurality of flip-flop circuits.

In Example 12, the subject matter of Example 11 includes a reference signal generator coupled to the plurality of delay generators, the reference signal generator to generate a plurality of reference signals and provide the plurality of reference signals to the plurality of delay generators, wherein at least one of the plurality of reference signals comprises a reference scan chain.

In Example 13, the subject matter of Example 12 includes, a feedback path coupled between the reference signal generator and outputs of the first plurality of flip-flop circuits, the second plurality of flip-flop circuits, and the third plurality of flip-flop circuits, the feedback path comprising a multiplexor coupled to a main capture flip-flop circuit.

In Example 14, the subject matter of Example 13 includes subject matter where the reference signal generator is to adjust a delay setting for one or more of the plurality of delay generators based on at least one feedback signal received from the first plurality of flip-flop circuits, the second plurality of flip-flop circuits, and the third plurality of flip-flop circuits via the feedback path.

In Example 15, the subject matter of Examples 11-14 includes, a reference delay generator coupled to the first plurality of flip-flop circuits, the second plurality of flip-flop circuits, and the third plurality of flip-flop circuits, the reference delay generator to receive a reference scan chain signal and delay the reference scan chain to generate the synchronized clock signal.

In Example 16, the subject matter of Example 15 includes, a clock mesh coupled to the plurality of delay generators and the corresponding clock terminals of the first plurality of flip-flop circuits, the second plurality of flip-flop circuits, and the third plurality of flip-flop circuits.

In Example 17, the subject matter of Example 16 includes, the clock mesh further comprising: a plurality of buffer pairs, and the plurality of buffer pairs coupled to the reference delay generator via an H-tree network.

In Example 18, the subject matter of Example 17 includes subject matter where the clock mesh is to receive the synchronized clock signal via the H-tree network, and supply the synchronized clock signal to the corresponding clock terminals of the first plurality of flip-flop circuits, the second plurality of flip-flop circuits, and the third plurality of flip-flop circuits.

In Example 19, the subject matter of Examples 11-18 includes subject matter where a delay generator of the plurality of delay generators comprises a plurality of serially connected delay cells, and wherein each delay cell of the plurality of serially connected delay cells comprises a first set of coarse delay cells and a second set of fine delay cells.

In Example 20, the subject matter of Examples 11-19 includes subject matter where a flip-flop circuit in any of the first plurality of flip-flop circuits, the second plurality of flip-flop circuits, and the third plurality of flip-flop circuits comprises: a flip-flop circuit configured to receive dual data inputs via a multiplexer; an inverting symmetric multiplexer tree coupled to the flip-flop circuit; and a rising select XOR gate coupled to the inverting symmetric multiplexer tree.

Example 21 is a method comprising: encoding a plurality of reference signals for communication to a corresponding plurality of delay generators; generating a delayed data input signal, a delayed enable signal, and a synchronized clock signal based on the plurality of reference signals; providing the delayed data input signal to a plurality of data input terminals of a memory circuit using a first plurality of flip-flop circuits; providing the delayed enable signal to a plurality of enable terminals of the memory circuit using a second plurality of flip-flop circuits; and providing the synchronized clock signal to corresponding clock terminals of the first plurality of flip-flop circuits and the second plurality of flip-flop circuits.

In Example 22, the subject matter of Example 21 includes, detecting at least one feedback signal received from the first plurality of flip-flop circuits and the second plurality of flip-flop circuits; and adjusting a delay setting for one or more of the plurality of delay generators based on the at least one feedback signal.

Example 23 is a device comprising one or more processors and memory coupled to the one or more processors. The memory comprises a first flip-flop circuit coupled to a data input terminal of a memory circuit; a second flip-flop circuit coupled to a clock terminal of the memory circuit; a third flip-flop circuit coupled to an output terminal of the memory circuit; and a reference delay generator coupled to a clock terminal of the first flip-flop circuit, a clock terminal of the second flip-flop circuit, and a clock terminal of the third flip-flop circuit.

In Example 24, the subject matter of Example 23 includes the memory further comprises: a data delay generator coupled to the first flip-flop circuit and the memory circuit, the data delay generator to receive a data input signal and delay the data input signal to generate a delayed data input signal, wherein the data delay generator is to communicate the delayed data input signal to a data input terminal of the first flip-flop circuit and the data input terminal of the memory circuit.

Example 25 is at least one machine-readable medium including instructions that, when executed by processing circuitry, cause the processing circuitry to perform operations to implement any of Examples 1-24.

Example 26 is an apparatus comprising means to implement any of Examples 1-24.

Example 27 is a system to implement any of Examples 1-24.

Example 28 is a method to implement any of Examples 1-24.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate embodiment. The scope of the embodiments disclosed herein is to be determined regarding the appended claims, along with the full scope of equivalents to which such claims are entitled.

What is claimed is:

1. An apparatus comprising:
a first flip-flop circuit coupled to a data input terminal of a memory circuit;
a second flip-flop circuit coupled to a clock terminal of the memory circuit;
a third flip-flop circuit coupled to an output terminal of the memory circuit; and
a reference delay generator coupled to a clock terminal of the first flip-flop circuit, a clock terminal of the second flip-flop circuit, and a clock terminal of the third flip-flop circuit.

2. The apparatus of claim 1, further comprising:
a data delay generator coupled to the first flip-flop circuit and the memory circuit, the data delay generator to receive a data input signal and delay the data input signal to generate a delayed data input signal.

3. The apparatus of claim 2, wherein the data delay generator is to communicate the delayed data input signal to a data input terminal of the first flip-flop circuit and the data input terminal of the memory circuit.

4. The apparatus of claim 1, further comprising:
a clock delay generator coupled to the second flip-flop circuit and the memory circuit, the clock delay generator to receive a memory clock signal and delay the memory clock signal to generate a delayed memory clock signal.

5. The apparatus of claim 4, wherein the clock delay generator is to communicate the delayed memory clock signal to a data input terminal of the second flip-flop circuit and the clock terminal of the memory circuit.

6. The apparatus of claim 1, wherein the output terminal of the memory circuit is coupled to a data input terminal of the third flip-flop circuit.

7. The apparatus of claim 1, further comprising:
a reference signal generator coupled to the reference delay generator, the reference delay generator to receive a reference signal generated by the reference signal generator and delay the reference signal to generate a synchronized clock signal.

8. The apparatus of claim 7, further comprising:
a clock mesh coupled to the reference delay generator, the clock terminal of the first flip-flop circuit, the clock terminal of the second flip-flop circuit, and the clock terminal of the third flip-flop circuit.

9. The apparatus of claim 8, the clock mesh further comprising:
a plurality of buffer pairs, the plurality of buffer pairs coupled to the reference delay generator via an H-tree network.

10. The apparatus of claim 9, wherein the clock mesh is to receive the synchronized clock signal via the H-tree network, and supply the synchronized clock signal to the clock terminal of the first flip-flop circuit, the clock terminal of the second flip-flop circuit, and the clock terminal of the third flip-flop circuit.

11. An apparatus comprising:
a plurality of delay generators comprising a data delay generator, an enable delay generator, and a reference delay generator;
a first plurality of flip-flop circuits coupled to the data delay generator to receive a delayed data input signal, and provide the delayed data input signal to a plurality of data input terminals of a memory circuit;
a second plurality of flip-flop circuits coupled to the enable delay generator to receive a delayed enable signal, and provide the delayed enable signal to a plurality of enable terminals of the memory circuit;
a third plurality of flip-flop circuits coupled to an output terminal of the memory circuit; and
the reference delay generator to provide a synchronized clock signal to corresponding clock terminals of the first plurality of flip-flop circuits, the second plurality of flip-flop circuits, and the third plurality of flip-flop circuits.

12. The apparatus of claim 11, further comprising:
a reference signal generator coupled to the plurality of delay generators, the reference signal generator to generate a plurality of reference signals and provide the plurality of reference signals to the plurality of delay generators, wherein at least one of the plurality of reference signals comprises a reference scan chain.

13. The apparatus of claim 12, further comprising:
a feedback path coupled between the reference signal generator and outputs of the first plurality of flip-flop circuits, the second plurality of flip-flop circuits, and the third plurality of flip-flop circuits, the feedback path comprising a multiplexor coupled to a main capture flip-flop circuit.

14. The apparatus of claim 13, wherein the reference signal generator is to adjust a delay setting for one or more of the plurality of delay generators based on at least one feedback signal received from the first plurality of flip-flop circuits, the second plurality of flip-flop circuits, and the third plurality of flip-flop circuits via the feedback path.

15. The apparatus of claim 11, further comprising:
a reference delay generator coupled to the first plurality of flip-flop circuits, the second plurality of flip-flop circuits, and the third plurality of flip-flop circuits, the reference delay generator to receive a reference scan chain signal and delay the reference scan chain to generate the synchronized clock signal; and
a clock mesh coupled to the plurality of delay generators and the corresponding clock terminals of the first plurality of flip-flop circuits, the second plurality of flip-flop circuits, and the third plurality of flip-flop circuits.

16. The apparatus of claim 15, the clock mesh further comprising:
a plurality of buffer pairs, the plurality of buffer pairs coupled to the reference delay generator via an H-tree network,
wherein the clock mesh is to receive the synchronized clock signal via the H-tree network, and supply the synchronized clock signal to the corresponding clock terminals of the first plurality of flip-flop circuits, the second plurality of flip-flop circuits, and the third plurality of flip-flop circuits.

17. The apparatus of claim 11, wherein a delay generator of the plurality of delay generators comprises a plurality of serially connected delay cells, and wherein each delay cell of the plurality of serially connected delay cells comprises a first set of coarse delay cells and a second set of fine delay cells.

18. The apparatus of claim 11, wherein a flip-flop circuit in any of the first plurality of flip-flop circuits, the second plurality of flip-flop circuits, and the third plurality of flip-flop circuits comprises:
a flip-flop circuit configured to receive dual data inputs via a multiplexer;
an inverting symmetric multiplexer tree coupled to the flip-flop circuit; and
a rising select XOR gate coupled to the inverting symmetric multiplexer tree.

19. A device comprising:
one or more processors; and
memory coupled to the one or more processors, the memory comprising:
a first flip-flop circuit coupled to a data input terminal of a memory circuit;
a second flip-flop circuit coupled to a clock terminal of the memory circuit;
a third flip-flop circuit coupled to an output terminal of the memory circuit; and
a reference delay generator coupled to a clock terminal of the first flip-flop circuit, a clock terminal of the second flip-flop circuit, and a clock terminal of the third flip-flop circuit.

20. The device of claim 1, wherein the memory further comprises:
a data delay generator coupled to the first flip-flop circuit and the memory circuit, the data delay generator to receive a data input signal and delay the data input signal to generate a delayed data input signal,
wherein the data delay generator is to communicate the delayed data input signal to a data input terminal of the first flip-flop circuit and the data input terminal of the memory circuit.
